(19) United States
(12) Patent Application Publication
(10) Pub. No.: US 2011/0005822 A1
(43) Pub. Date: Jan. 13, 2011

(54) STRUCTURE OF A PACKAGE FOR ELECTRONIC DEVICES AND METHOD FOR MANUFACTURING THE PACKAGE

(76) Inventor: Yuuki Momokawa, Tokyo (JP)

Correspondence Address: Mr. Jackson Chen, 6535 N. STATE HWY 161, IRVING, TX, 75039, US

(21) Appl. No.: 12/446,342

(22) PCT Filed: Oct. 19, 2007
(86) PCT No.: PCT/JP2007/070476

§ 371 Date: Apr. 20, 2009

(30) Foreign Application Priority Data
Oct. 20, 2006 (JP) 2006-286183

(51) Int. Cl. H05K 1/18; B23K 31/02; B23K 1/20

(52) U.S. Cl. 174/260; 228/256

(57) ABSTRACT

A package structure for an electronic device having an electronic device mounted on a substrate; the electronic device including an external electrode; the substrate including an interconnection and an electrode pad for mounting the electronic device thereon. Part or entire of the interconnection and part or entire of the electrode pad of the substrate are formed of the same material; and the external electrode of the electronic device is joined to the electrode pad of the substrate with a joining part which is the same material as the interconnection and the electrode pad.

This application is the National Phase of PCT/JP2007/070476, filed Oct. 19, 2007, which claims priority based on the Japanese Patent Application No. 2006-286183 filed on Oct. 20, 2006, the disclosure of which is incorporated herein in its entirety by reference thereto.

### TECHNICAL FIELD

This invention relates to a structure of a package for an electronic device(s) and a method for manufacturing the package for the electronic devices having this structure.

### BACKGROUND ART

The structure of a package for electronic devices, employing a circuit board according to the background technique, and a method for manufacturing the package for electronic devices, having this structure, are now described in detail with reference to FIG. 23.

A copper-lined laminated plate is formed by joining a copper foil to an insulating sheet under pressuring and heating. The insulating sheet has been provided by allowing an epoxy resin or a phenol resin, for example, to seep into a substrate of paper, glass substrate or polyester fibers. The surface of the copper-lined laminated plate is coated with a photosensitive resin. Then, using a mask for forming a conductor pattern, only a conductor pattern part is exposed and developed to form an etching resist having the same shape as that of the conductor pattern.

The surface of the copper-lined laminated plate is then etched to remove copper from an area other than the area of the etching resist. The etching resist is then removed to form a copper conductor pattern. To protect the conductor, a solder resist is then formed on an area of the substrate other than the substrate area where to load an electronic device.

The process described above is the method for manufacturing a single-sided substrate. If desired to fabricate a multi-layered substrate, conductors are formed on both sides of the substrate. A copper-lined laminated plate then is mounted on each substrate surface, and a via is bored for electrical conduction across the two layers. A conductor pattern is then formed by the same method as described above.

To mount an electronic device on the surface of the circuit board, completed as described above, a solder paste is supplied to an electrode pad part, adapted for loading the device thereon, using a metal mask. The device is loaded on the solder paste so that external electrodes will contact with the solder paste. Heating by reflow, for example, is then carried out to join the electronic device to the circuit board to complete a package for electronic devices that includes the desired electronic devices mounted on the circuit board.

In JP Patent Kokai Publication No. JP-P2006-196896A (Patent Document 1), there is disclosed a method for manufacturing a package for electronic devices pertaining to the background art. Patent Document 1 discloses apparatus and methods for packaging a semiconductor chip. The packaging apparatus includes a plating unit for forming an electrically conductive plating layer on an external terminal of a semiconductor chip package, and a reflow unit for melting the plating layer. The reflow unit is arranged in alignment with the plating unit. The packaging apparatus disclosed allows for effective suppression of generation of whiskers in the plating layer at the external terminal and assures mass productivity and economic profitability such as by cost reduction.

Patent Document 1: JP Patent Kokai Publication No. JP-P2006-196896A

### SUMMARY

The disclosure of Patent Document is to be incorporated by reference herein. The following is an analysis of the related technique from the side of the present invention.

With the package for electronic devices of the related technique, the electronic devices are mounted on a wiring substrate completed beforehand. Thus, in case the electronic device configuration is changed from QFP (Quad Flat Package) to BGA (Ball Grid Array), with the position of the external electrode being correspondingly changed, it is necessary to redo the packaging operation from the stage of fabrication of a substrate (mask for a photoresist).

In addition, with the related technique, it is necessary to fabricate the substrate by a number of manufacturing steps, as described above, with resulting increase in cost. Moreover, the disclosed technique is not desirable from the perspective of environmental protection, because the copper material other than that for wiring is removed in its entirety, and the used etching solution results in a waste liquid.

Further, with the method for manufacturing a substrate according to the related technique, it is necessary to use a step of mounting electronic devices on the substrate, in addition to the substrate manufacturing step, thus increasing the number of the processing steps. Also, due to recent preference of a leadless solder paste, the heating furnace has to be set to a higher temperature, thus increasing the energy consumption.

In view of the above depicted status of the art, it is a first object of the present invention to provide a package for electronic devices that may cope readily with diversification of the configurations of the electronic devices and that is benign to environment in view of the reduced number of manufacturing process steps and reduced consumption of resources.

It is a second object of the present invention to provide a method for manufacturing a package for electronic devices that may deal more readily with diversification of the configurations of the electronic devices and that is benign to environment in view of the reduced number of manufacturing process steps and reduced consumption of the resources.

For accomplishing the above first object, the present invention provides, in a first aspect, a package structure for an electronic device (component or part) having an electronic device mounted on a substrate, in which the electronic device includes an external electrode, and the substrate includes an interconnection and an electrode pad for mounting the electronic device thereon. Part or entire of the interconnection and part or entire of the electrode pad of the substrate are formed of the same material, and the external electrode of the electronic device is joined to the electrode pad of the substrate with a joining part which is of the same material as the interconnection and the electrode pad.

In a package structure of a second aspect of the present invention, part or entire of an interconnection and part or entire of an electrode pad of the substrate are formed of the same material as and thus formed integrally with a joining part that joins the electrode pad of the substrate to the external electrode of the electronic device.

In a package structure of a third aspect of the present invention, part of an interconnection and part or entire of an electrode pad of the substrate are connected to and extend from an electrically conductive layer provided preliminarily on the substrate. The external electrode of the electronic device is joined to the electrode pad of the substrate by a joining part which is of the same material as a material of the interconnection and the electrode pad.

In a package structure of a fourth aspect of the present invention, part of an interconnection and part or entire of an electrode pad of the substrate are connected to and extend from an electrically conductive layer provided preliminarily on the substrate. The interconnection and the electrode pad are formed of the same material as and are formed integrally with a joining part that joins the electrode pad to the external electrode of the electronic device.

For accomplishing the above second object, the present invention provides, in a fifth aspect, a method for manufacturing a package of an electronic device having an electronic device mounted on a substrate, in which the electronic device includes an external electrode, and the substrate includes an interconnection and an electrode pad for mounting the electronic device thereon. Part or entire of the interconnection of the substrate and part or entire of the electrode pad of the substrate are formed of the same material as a joining part that joins the electrode pad of the substrate to the external electrode of the electronic device by a lumped forming operation.

The present invention provides, in a sixth aspect, a method for manufacturing a package in which part or entire of an interconnection of a substrate and part or entire of an electrode pad of the substrate, and a joining part that joins the electrode pad of the substrate and the external electrode of the electronic device are formed of the same material by a lumped operation.

The present invention provides, in a seventh aspect, a method for manufacturing a package in which part or entire of an interconnection of a substrate and part or entire of an electrode pad of the substrate are connected to and extend from an electrically conductive layer or land provided preliminarily on the substrate. The interconnect, the electrode pad and a joining part that joins the electrode pad and the external electrode of the electronic device are formed of the same material by a lumped forming operation.

The present invention provides, in an eighth aspect, a method for manufacturing a package comprising the steps of: forming part or entire of an interconnection and part or entire of the shape of an electrode pad of a substrate by printing an electrically conductive paste or an electrically conductive ink; loading an electronic device while the electrically conductive paste or the electrically conductive ink is as yet in an uncured state; loading an external electrode of an electronic device in an area printed to a shape of the electrode part; and curing the electrically conductive paste or the electrically conductive ink to form the interconnection of the substrate, the electrode pad of the substrate and a joining part that joins the electrode pad of the substrate to the external electrode with the same material by a lumped forming operation.

The present invention provides, in a ninth aspect, a method for manufacturing a package comprising the steps of: forming part or entire of an interconnection and part or entire of the shape of an electrode pad of the substrate by printing an electrically conductive paste or an electrically conductive ink so that the part or entire of the interconnection and the part or entire of the shape of the electrode pad of the substrate connect to and extend from at least one of an electrically conductive layer and a land provided preliminary on the substrate; loading the electronic device while the electrically conductive paste or the electrically conductive ink is as yet in an uncured state; loading the external electrode of the electronic device in an area printed to the shape of the electrode part; and curing the electrically conductive paste or the electrically conductive ink to form the interconnection and the electrode pad of the substrate and a joining part that joins the electrode pad of the substrate to the external electrode of the electronic device with the same material by a lumped forming operation.

### (Operation)

According to the present invention, a package for an electronic device may be manufactured without the necessity of remodeling the substrate itself even in case the configuration of the electronic device being packaged has been changed.

Moreover, according to the present invention, in which at least part of the interconnection and the electrode pad of a substrate and a joining part used for mounting an electronic device to the substrate are formed of the same material, the number of process steps and the volume of wasted materials may be reduced.

The present invention gives rise to the at least one of the following meritorious effects.

A first meritorious effect is that, even in case the configuration of the electronic device being packaged is changed, it is unnecessary to remodel the substrate itself, but it is only necessary to change a drawing pattern of the electrically conductive paste or ink to suit to a new configuration of the electronic device. It is thus possible to cope with diversification of the electronic devices extremely readily.

A second meritorious effect is that at least part of the interconnection and the electrode pad of a substrate and a joining part used for mounting an electronic device to the substrate are formed of the same material, and hence the number of process steps and wastage of the material may be reduced. It is thus possible to provide a package for electronic devices that is benign to environment.

### BRIEF DESCRIPTION OF THE DRAWINGS

FIG. 1 is a cross-sectional plan view and a cross-sectional side view, schematically showing an example basic form of a package structure according to a first exemplary embodiment of the present invention.

FIG. 2 is a cross-sectional view schematically showing an example basic form of a package structure according to a second exemplary embodiment of the present invention.

FIG. 3 is a cross-sectional view schematically showing an example basic form of a package structure according to a third exemplary embodiment of the present invention.

FIG. 4 is a cross-sectional view schematically showing an example basic form of a package structure according to a fourth exemplary embodiment of the present invention.

FIG. 5 is a cross-sectional view schematically showing an example basic form of a package structure according to a fifth exemplary embodiment of the present invention.

FIG. 6 is a cross-sectional view schematically showing an example basic form of a package structure according to a sixth exemplary embodiment of the present invention.

FIG. 7 is a cross-sectional view schematically showing an example basic form of the package structure according to the sixth exemplary embodiment.

FIG. 8 is a cross-sectional view schematically showing an example basic form of a package structure according to a seventh exemplary embodiment of the present invention.

FIG. 9 is a cross-sectional view schematically showing an example basic form of the package structure according to the seventh exemplary embodiment of the present invention.

FIG. 10 is a cross-sectional view schematically showing an example basic form of a package structure according to an eighth exemplary embodiment of the present invention.

FIG. 11 is a cross-sectional view schematically showing an example basic form of the package structure according to the eighth exemplary embodiment.

FIG. 12 is a cross-sectional view schematically showing an example basic form of the package structure according to the eighth exemplary embodiment.

FIG. 13 is a cross-sectional view schematically showing an example basic form of the package structure according to the eighth exemplary embodiment.

FIG. 14 is a cross-sectional view schematically showing an example basic form of a package structure according to a ninth exemplary embodiment of the present invention.

FIG. 15 is a cross-sectional view schematically showing an example basic form of a package structure according to a tenth exemplary embodiment of the present invention.

FIG. 16 is a cross-sectional view schematically showing an example basic form of a package structure according to an eleventh exemplary embodiment of the present invention.

FIG. 17 is a cross-sectional view schematically showing an example basic form of a package structure according to a twelfth exemplary embodiment of the present invention.

FIG. 18 is a cross-sectional view schematically showing an example basic form of a package structure according to a thirteenth exemplary embodiment of the present invention.

FIG. 19 is a cross-sectional view schematically showing an example basic form of a package structure according to a fourteenth exemplary embodiment of the present invention.

FIG. 20 is a cross-sectional view schematically showing an example basic form of a package structure according to a fifteenth exemplary embodiment of the present invention.

FIG. 21 is a cross-sectional view schematically showing an example basic form of a package structure according to a sixteenth exemplary embodiment of the present invention.

FIG. 22 is a cross-sectional view schematically showing an example basic form of the package structure according to the sixteenth exemplary embodiment of the present invention.

FIG. 23 is a schematic view for illustrating a package structure and a package manufacturing method according to a background technique.

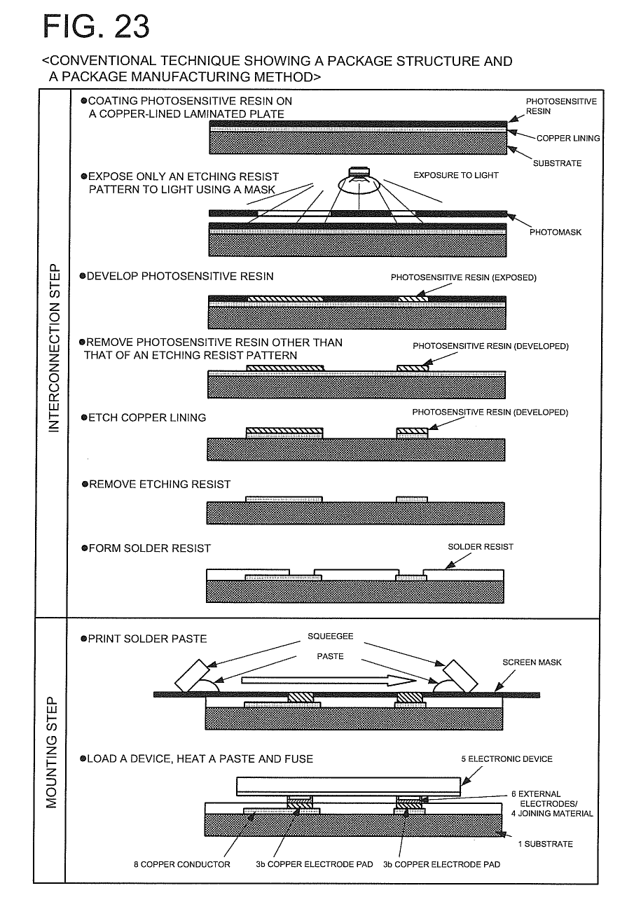

### EXPLANATIONS OF SYMBOLS

1: substrate
2: interconnection
3: electrode pad
3b: copper electrode pad
4: joining material (boarding material)
5: electronic device (component or part)
6: external electrode
7: insulating layer
8: copper conductor
9: via
10: insulating resin
11: interlayer insulating film
12: stage (releasable layer)
13: stage (with recess)

### PREFERRED MODES FOR CARRYING OUT THE INVENTION

Preferred exemplary embodiments of the present invention are now described.

It is preferred that an interconnection (or wiring), an electrode pad and a joining material are formed of an electrically conductive paste or electrically conductive ink.

It is preferred that the interconnection, electrode pad and the joining material are formed of an electrically conductive paste or an electrically conductive ink containing metallic particles, sized 5 μm or less, as electrically conductive fillers.

It is preferred that the interconnection, electrode pad and the joining material are formed of an electrically conductive paste or an electrically conductive ink containing fine metallic particles, sized 20 nm or less, as at least a portion of the electrically conductive fillers.

It is also preferred the interconnection, electrode pad and the joining material are formed of both an electrically conductive paste or an electrically conductive ink containing metallic particles, sized 5 μm or less, and an electrically conductive paste or an electrically conductive ink containing fine metallic particles, sized 20 nm or less.

It is moreover preferred that the fine metallic particles, sized 20 nm or less, are contained in an amount of 5 to 30 wt % in the electrically conductive paste or electrically conductive ink.

It is further preferred that the resin material of an electrode pad portion of the substrate is thicker in thickness than the interconnect portion.

The electrically conductive paste or ink may be applied in lump (or all together) at a time by screen printing, applied by a dispenser, or applied in accordance with an ink jet system.

In forming the substrate, the resin material that forms the electrode pad portion is desirably thicker in thickness than the interconnection portion.

Referring to the drawings, a package structure according to the present invention and a method for manufacturing a package having this package structure will be described in detail.

### First Exemplary Embodiment

A package structure according to a first exemplary embodiment of the present invention is now described.

### (Formulation of the First Exemplary Embodiment)

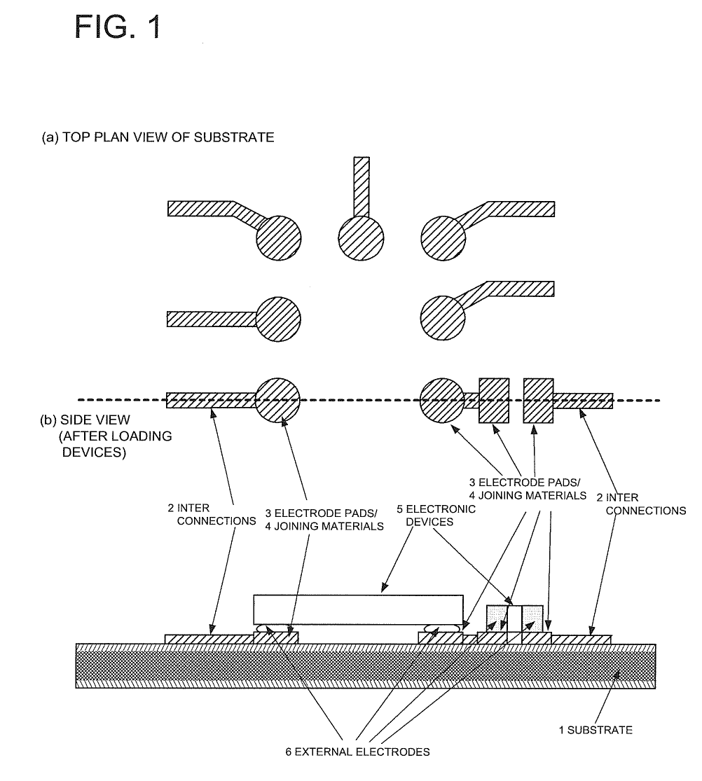

FIG. 1 schematically shows an illustrative basic form of a package structure of the first exemplary embodiment of the present invention. (a) of FIG. 1 depicts an top plan view of a substrate, and (b) of FIG. 1 depicts a cross-sectional view of the substrate after mounting a device(s) thereon.

The package structure, shown in FIG. 1, includes an interconnection 2 formed on the surface of the substrate 1, an electrode pad 3, an electronic device (or component) 5, an external electrode 6, and a joining material 4 that joins the electrode pad 3 and the external electrode 6 of the electronic device 5 together. The interconnection 2, electrode pad 3 and the joining material 4 are all formed of the same material.

With the present exemplary embodiment, the electrode pad serves simultaneously as the joining material 4.

The electrically conductive members (the interconnection 2, electrode pad 3 and the joining material 4) may be formed of, for example, a sintered mass of fine metallic particles (fine particles of gold, silver or copper) or an electrically conductive paste or an electrically conductive ink (including an organic-inorganic composite material in which electrically conductive fine particles are dispersed). Those electrically conductive members are preferably formed of a material that may be cured or sintered at a temperature not higher than the melting point of the external electrode 6.

For high density packaging of electronic devices in the package structure of the present exemplary embodiment, it is preferred to narrow down the pitch of the interconnections 2 and the electrode pads 3. To this end, it is preferred to use an electrically conductive paste or an electrically conductive ink, containing metallic particles, sized 5 μm or less, operating as fillers, as a feedstock material for the interconnections 2 and the electrode pads 3. It is more preferred to use the electrically conductive paste or the electrically conductive ink, containing fine metallic particles, sized 20 nm or less, as the feedstock material for the interconnections 2 and the electrode pads 3. The electrically conductive paste or the electrically conductive ink, containing metallic particles, sized 5 μm or less, and also containing fine metallic particles, sized 20 nm or less, as fillers, may also be used as a feedstock material for the interconnections 2 and the electrode pads 3. Preferably, 5 to 30 wt % of the fine metal particles, with the particle size 20 nm or less, are contained in the electrically conductive paste or ink. The interconnections 2 and the electrode pads 3 of the present exemplary embodiment, containing these fine metallic particles, may not only cope with narrowing down of the pitch, but also contribute to improved electrical conductivity as a result of fusion of the fine particles to one another.

The present exemplary embodiment shows a case where the electronic device is mounted only on one substrate side. The electronic devices may be mounted in similar manner on both sides of the substrate 1 as well.

The attaching resin portion of the electrode pad 3 to the substrate may be thicker in thickness than the attaching portion of the interconnection 2.

The method for manufacturing the package structure with respective exemplary embodiments, including the present exemplary embodiment, will be described subsequently.

### (Meritorious Effect of the First Exemplary Embodiment)

With the above-described package structure of the present exemplary embodiment, the device loading positions, formulations of the loaded devices, or the pitch of the external electrodes, may be changed as desired, thus achieving a package with a high degree of designing freedom.

The reason is that, if the formulation of electronic devices, used for the package for the electronic devices, has been changed, it is unnecessary to remodel the substrate 1 itself. It is only necessary to change a drawing pattern of the electrically conductive paste or ink in agreement with the so changed formulation of the electronic devices.

That is, if, with the package structure of the present exemplary embodiment, the formulation of electronic devices, used for the package for the electronic devices, is changed, it is unnecessary to remodel the substrate 1 itself. In such case, it is only necessary to change a screen mask for printing the electrically conductive paste or ink or drawing pattern data in agreement with the formulation of the electronic device 5. Hence, the present exemplary embodiment may deal more readily with diversification of the electronic devices.

In addition, with the package structure of the present exemplary embodiment, the number of process steps as well as the volume of wasted devices may be lesser than those of the background technique. Hence, the product provided may be lower in cost and more benign to environment.

The reason is that at least a part of the interconnections 2 and the electrode pads 3 of the substrate 1 and a mounting part of the electronic device to the substrate 1 are formed of the same material, and hence the number of the steps and the volume of wasted devices may be reduced.

That is, with the packaging structure of the present exemplary embodiment, at least a part of the interconnections 2 and the electrode pads 3 of the substrate 1 and a mounting part of the electronic device to the substrate 1 are formed of the same material, so that it is possible to reduce the number of the steps and the volume of wasted devices. Moreover, since the joining material is the electrically conductive paste or ink, the design temperature of the heating furnace may be lower than in case the leadless solder is used, thus contributing to energy saving. It is thus possible to provide a method for manufacturing a package for electronic devices that is benign to environment.

### Second Exemplary Embodiment

A package structure of a second exemplary embodiment of the present invention is now described.

### (Formulation of the Second Exemplary Embodiment)

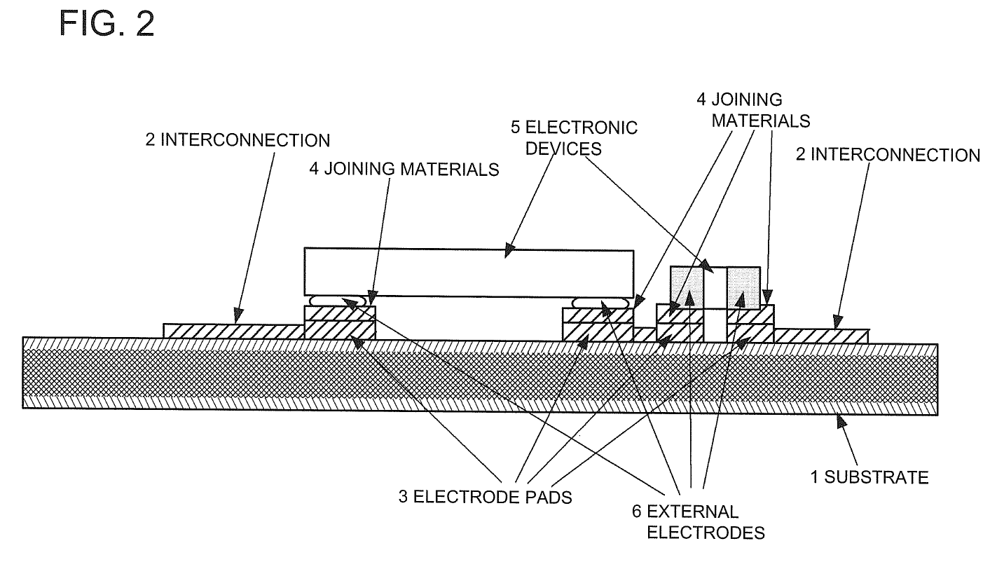

FIG. 2 depicts a cross-sectional view schematically showing an illustrative basic form of a package structure according to a second exemplary embodiment of the present invention. With the present second exemplary embodiment, a joining material 4 is provided as a separate member.

The package structure, shown in FIG. 2, includes a substrate 1, interconnections 2, electrode pads 3, electronic devices 5, external electrodes 6 and joining materials 4. The interconnections 2, electrode pads 3, electronic devices 5, the external electrodes 6 and the joining materials 4 are formed on the substrate 1. The joining materials 4 serve for joining the electrode pads 3 and the external electrodes 6 of the electronic devices 5 to each other. The interconnections 2, electrode pads 3 and the joining material 4 are all formed of the same material.

In the present exemplary embodiment, the joining materials 4 are provided as separate members on the electrode pads 3 after forming the interconnections 2 and the electrode pads 3, thus in a manner distinct from the case of the above-described first exemplary embodiment.

The electrically conductive members (interconnections 2, electrode pads 3 and joining materials 4) may be formed of, for example, sintered fine metallic particles, such as sintered fine particles of gold, silver or copper, and an electrically conductive paste or ink, inclusive of an organic-inorganic composite material in which are dispersed fine electrically conductive particles. Those electrically conductive members are preferably formed of a material that may be cured or sintered at a temperature not higher than the melting temperature of the external electrodes 6.

For high density packaging of electronic devices in the package structure of the present exemplary embodiment, it is preferred to narrow down the pitch of the interconnections 2 and the electrode pads 3. To this end, it is preferred that an electrically conductive paste or ink, containing metallic particles sized 5 μm or less, as electrically conductive fillers, is used as a feedstock material for the interconnections 2 and the electrode pads 3. It is more preferred that an electrically conductive paste or ink, containing fine metallic particles, sized 20 nm or less, as electrically conductive fillers, is used as a feedstock material for the interconnections 2 and the electrode pads 3. The electrically conductive paste or ink, containing metallic particles sized 5 μm or less and fine metallic particles, sized 20 nm or less, as electrically conductive fillers, may also be used as a feedstock material for the interconnections 2 and the electrode pads 3. The fine metallic particles, sized 20 nm or less, are preferably contained in the electrically conductive paste or ink in an amount of 5 to 30 wt %. The interconnections 2 and the electrode pads 3 of the present exemplary embodiment, containing these fine metallic particles, may not only cope with narrowing down of the pitch, but also contribute to improved electrical conductivity as a result of fusion of the fine particles to one another.

The present exemplary embodiment shows a case where the electronic device is loaded only on one substrate side. The electronic devices may be mounted in similar manner on both sides of the substrate 1 as well.

In the above formulation in which the joining material 4 is layered on the electrode pad 3, the electrode pad 3 and the joining material 4 are of the same material. However, if the joined state may be provided at the time of forming the interconnect 2 and the electrode pad 3 and the joining thereof to the electronic device, the electrode pad 3 and the joining material 4 may be of materials different from each other. It is however more desirable that the electrode pad and the joining material are formed of the same material (electrically conductive resin).

### (Meritorious Effect of the Second Exemplary Embodiment)

With the above-described package structure of the present exemplary embodiment, it is possible to change the device loading position, formulation of the devices loaded or the pitch of the external electrodes, as in the first exemplary embodiment described above. It is thus possible to manufacture a package with a high designing degree of freedom. In addition, since the number of the process steps or the volume of the wasted devices may be lesser than those with the background technique, it is possible to manufacture a product lower in cost and which is more benign to environment.

### Third Exemplary Embodiment

A package structure according to a third exemplary embodiment of the present invention is now described.

With the packaging structure of the third exemplary embodiment of the present invention, the parts of the interconnections 2 not used for mounting the electronic devices 5 may be coated with an insulating layer 7.

### (Formulation of the Third Exemplary Embodiment)

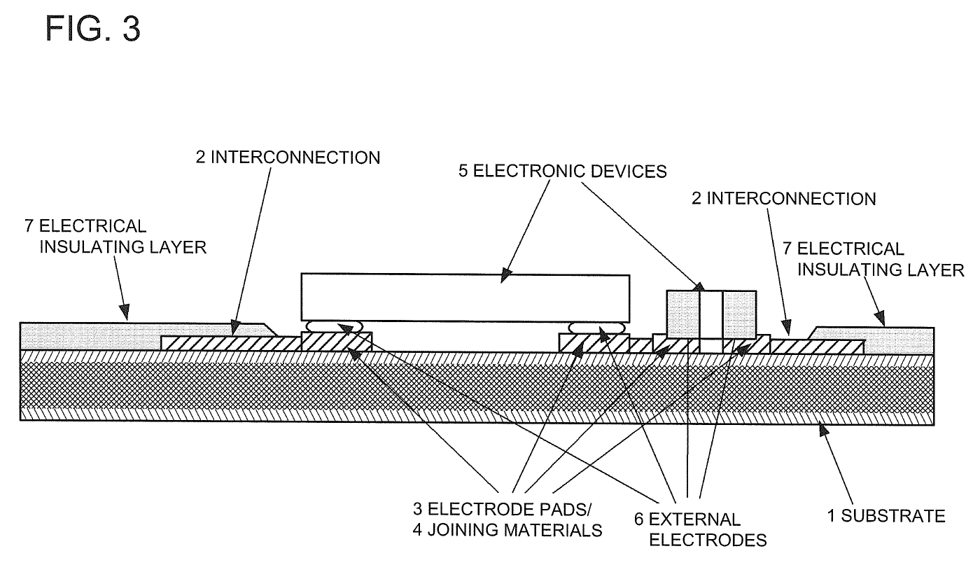

FIG. 3 depicts a cross-sectional view schematically showing a package structure having an insulating layer 7 according to the third exemplary embodiment of the present invention.

The package structure, shown in FIG. 3, is constructed and designed to prevent migration of ingredients of the interconnections 2 and resulting shorting of the interconnections 2 in case of using the package structure under a high humidity environment. The insulating layer 7, used for this purpose, is formed of resin having electrical insulating properties for example.

FIG. 3 shows an illustrative structure in which the insulating layer 7 is provided in the package of the first exemplary embodiment. However, the insulating layer is similarly effective to prevent migration in other exemplary embodiments of the present invention.

The present exemplary embodiment shows a case where the electronic device is mounted only on one substrate side. The electronic device may also be mounted in similar manner on both sides of the substrate 1.

### (Effect of the Third Exemplary Embodiment)

With the above-described package structure of the present exemplary embodiment, it is possible to change the device loading position as well as the formulation or the pitch of the devices loaded, as in the above-described exemplary embodiments. It is thus possible to manufacture a package with a high designing degree of freedom. In addition, since the number of the process steps or the volume of the wasted devices may be lesser than those with the background technique, it is possible to manufacture a product lower in cost and which is more benign to environment.

Moreover, with the package structure of the present exemplary embodiment, in which the parts of the interconnections other than the attaching parts of the electronic devices are coated with the insulating layer 7, the mounted devices may be improved in reliability. It is thus possible to provide a package of higher reliability than with the previous exemplary embodiments.

### Fourth Exemplary Embodiment

A package structure according to a fourth exemplary embodiment of the present invention is now described.

### (Formulation of the Fourth Exemplary Embodiment)

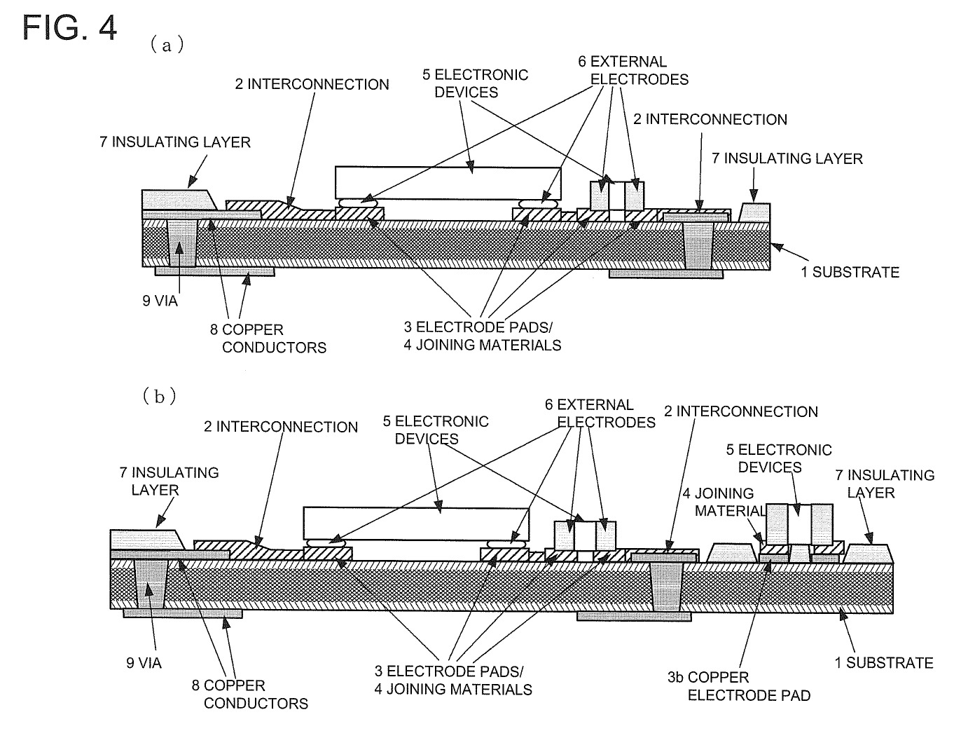

FIG. 4 schematically shows an illustrative basic form of a package structure according to a fourth exemplary embodiment of the present invention. Specifically, (a) of FIG. 4 depicts a cross-sectional view schematically showing an example of a package structure for electronic devices having an interconnection extended from an electrically conductive layer (copper conductor) on each side of a double-sided substrate. (b) of FIG. 4 shows a modification of the package structure shown in (a) of FIG. 4.

The package structure shown in (a) of FIG. 4 includes interconnections 2, electrode pads 3 and joining materials 4, all formed of the same material. External electrodes 6 of electronic devices 5 are joined to the electrode pads 3 and to the joining materials 4. The interconnections 2 are formed as extension of electrically conductive layers (copper conductors) 8 provided preliminarily on the surface of the substrate 1.

In the present exemplary embodiment, the substrate 1 is double-sided. The copper conductors 8 on the upper and lower surfaces of the substrate are connected to each other by vias 9.

In (a) of FIG. 4, the electrode pads 3 serve as the joining materials 4 and vice versa, as in the first exemplary embodiment. However, the joining materials 4 may also be provided as separate members on the electrode pads.

In the present exemplary embodiment, as in the first and second exemplary embodiments, the electrically conductive members (the interconnections 2, electrode pads 3 and the joining materials 4) may each be formed by a sintered mass of fine metallic particles, such as fine particles of gold, silver or copper, or by an electrically conductive paste or ink including an organic-inorganic composite material in which are dispersed electrically conductive fine particles. Preferably, those electrically conductive members are formed of materials that may be cured or sintered at a temperature not higher than the melting point of the external electrodes 6. Also, the electrically conductive members are preferably formed of the electrically conductive paste or ink, containing fine metallic particles with the particle size roughly of 20 nm, as a feedstock material.

The present exemplary embodiment shows a case where the electronic device is mounted only on one substrate side. The electronic devices may be mounted in similar manner on both sides of the substrate 1 as well.

Further, as shown in (b) of FIG. 4, the electronic device(s) 5 may be mounted on copper electrode pads 3b provided preliminarily on the substrate 1. Preferably, the aforementioned electrically conductive resin or the electrically conductive ink is supplied at a time onto the copper electrode pads, as the joining materials 4, so as to be cured and joined together in situ along with the interconnections 2. However, the solder or an electrically conductive resin may be supplied separately for joining

### (Meritorious Effect of the Fourth Exemplary Embodiment)

With the above-described package structure of the present exemplary embodiment, as in the first exemplary embodiment, described above, device loading positions, formulations of the device(s) loaded or the pitch of the external electrodes may be changed without remodeling the substrate. It is thus possible to manufacture a package with a high designing degree of freedom. In addition, since the number of the process steps or the volume of the wasted devices may be lesser than those with the background technique, it is possible to provide a product lower in cost and which is more benign to environment.

### Fifth Exemplary Embodiment

A package structure according to a fifth exemplary embodiment of the present invention is now described.

### (Formulation of Fifth Exemplary Embodiment)

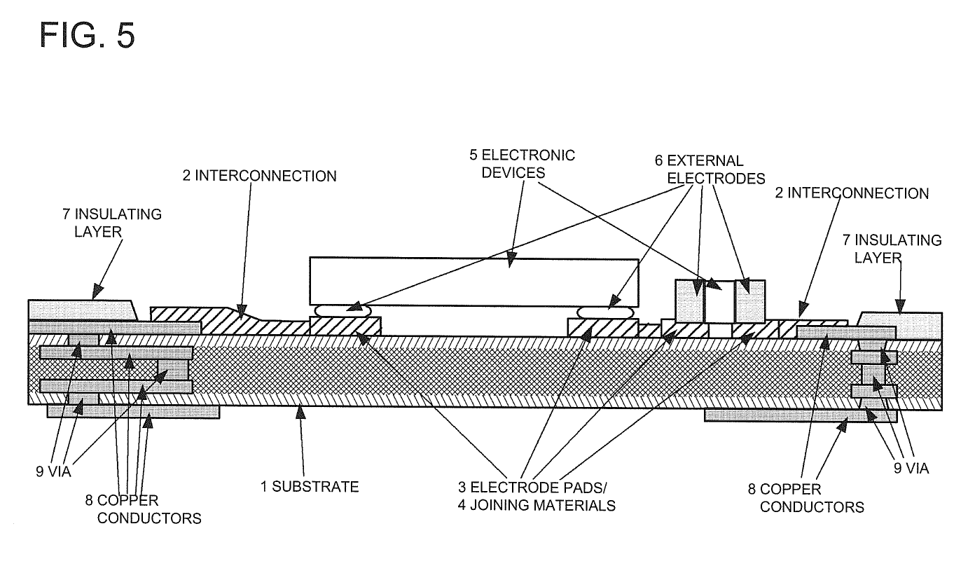

FIG. 5 depicts a cross-sectional view schematically showing an illustrative basic form of a package structure having interconnections extended from a copper conductor on a multi-layer substrate according to a fifth exemplary embodiment of the present invention.

In the package structure, shown in FIG. 5, interconnections 2, electrode pads 3 and joining materials 4 are formed of the same material. The interconnections 2 are extended from an electrically conductive layer (copper conductor (wiring) 8) provided preliminarily on the surface of the substrate 1. External electrodes 6 of the electronic devices 5 are joined to the electrode pads 3 and to the joining materials 4.

In the present exemplary embodiment, the substrate 1 is multi-layered. The present exemplary embodiment differs from the above-described fourth exemplary embodiment in that the copper conductor 8 on the front surface, that in inner layers and that on the back surface are interconnected through vias 9.

In FIG. 5, the electrode pads 3 serve as the joining materials 4 and vice versa, as in the first exemplary embodiment. However, the joining materials 4 may also be provided as separate members on the electrode pads 3, as in the second exemplary embodiment described above.

In the present exemplary embodiment, as in the first and second exemplary embodiments, the electrically conductive members (the interconnections 2, electrode pads 3 and the joining materials 4) may each be formed as a sintered mass of fine metallic particles, such as fine particles or gold, silver or copper, or by an electrically conductive paste or ink inclusive of an organic-inorganic composite material in which are dispersed electrically conductive fine particles. Preferably, those electrically conductive members are formed of materials that may be cured or sintered at a temperature not higher than the melting point of the external electrodes 6. The electrically conductive members are preferably manufactured from the electrically conductive paste or ink, containing fine metallic particles with the particle size roughly of 20 nm, as a feedstock material.

The present exemplary embodiment shows a case where the electronic device is mounted only on one substrate side. However, the electronic devices may be mounted in similar manner on both sides of the substrate 1.

Further, the device(s) may also be mounted on the copper electrode pads 3b, provided preliminarily on the substrate 1, as in the above-described first exemplary embodiment.

### (Meritorious Effect of the Fifth Exemplary Embodiment)

With the above-described package structure of the present exemplary embodiment, as in the above-described fourth exemplary embodiment, it is possible to change the device loading positions as well as the formulation of the devices loaded or the pitch of the external electrodes without remodeling the substrate 1. It is thus possible to manufacture a package with a high designing degree of freedom. In addition, since the number of the process steps or the volume of the wasted devices may be lesser than those with the background technique, it is possible to provide a product lower in cost and which is more benign to environment.

### Sixth Exemplary Embodiment

A package structure according to a sixth exemplary embodiment of the present invention is now described.

### (Formulation of the Sixth Exemplary Embodiment)

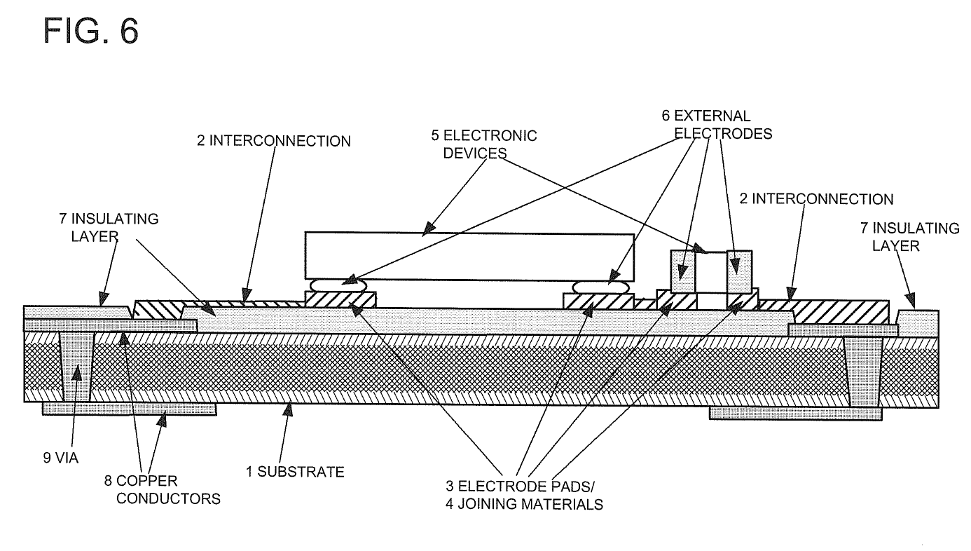

FIG. 6 depicts a cross-sectional view schematically showing a basic illustrative form of a package structure having interconnections extended onto an insulating layer of a substrate from the copper conductor (wiring) on each side of the double-sides substrate according to the sixth exemplary embodiment of the present invention.

The package structure shown in FIG. 6 includes interconnections 2, electrode pads 3 and joining materials 4, all formed of the same material. The interconnections 2 are formed by extension from the copper conductor (wiring) 8 provided beforehand on the surface of the substrate 1 and are formed on an insulating layer 7 equally provided beforehand on the substrate surface. External electrodes 6 of electronic devices 5 are joined to the electrode pads 3/joining materials 4.

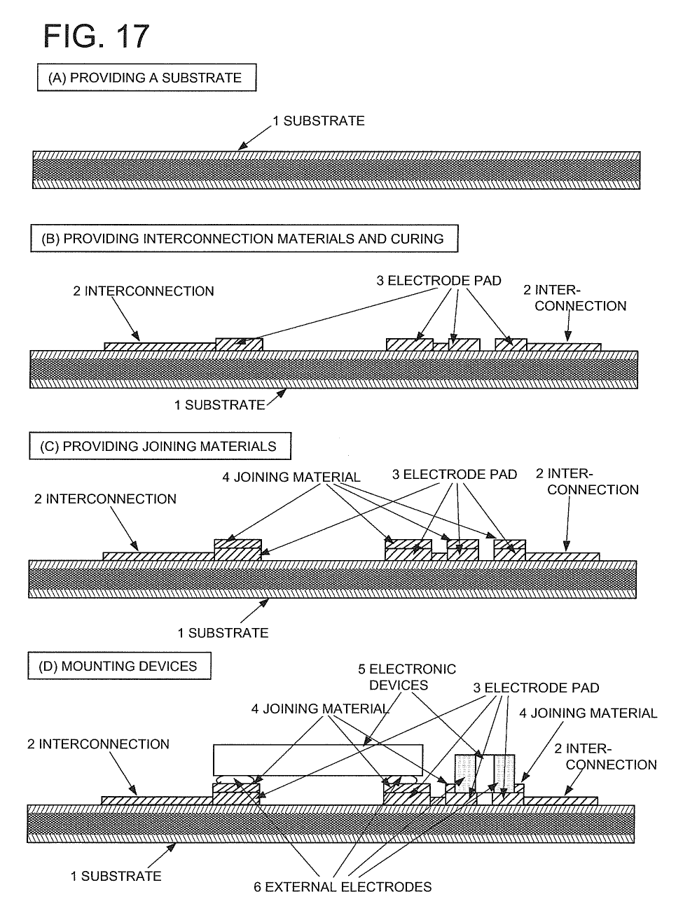

With the present exemplary embodiment, the substrate 1 is double-sided. The copper conductor (wiring) 8 on the front substrate side is connected through vias 9 to the copper conductor (wiring) 8 on the back substrate side. As a matter of course, the substrate 1 is not necessarily double-sided and may also be multi-layered, as shown in FIG. 17. It may also be single-sided, although not shown.

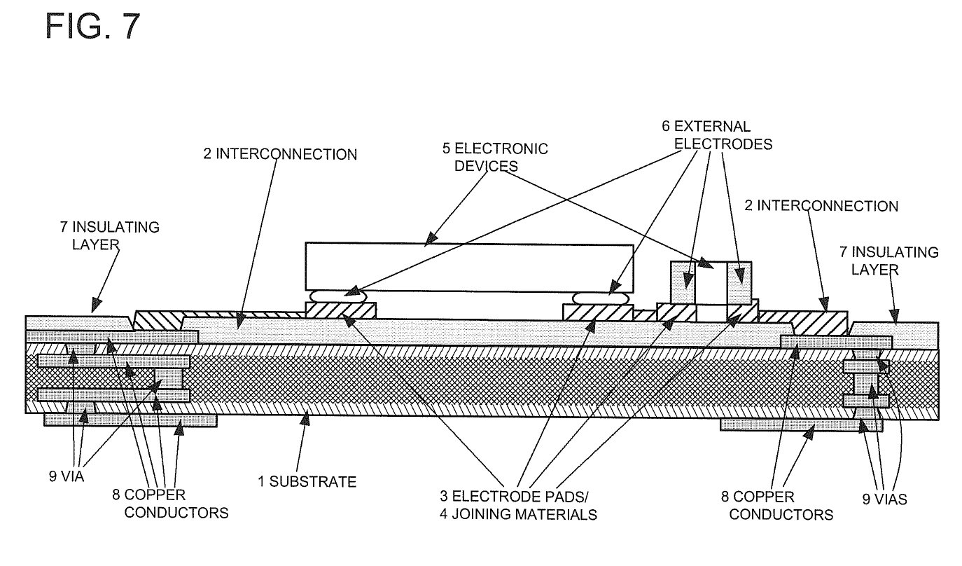

In FIGS. 6 and 7, the electrode pads 3 also serve as the joining materials 3 and vice versa. Alternatively, the joining materials 4 may be mounted as separate members on the electrode pads 3, as in the case of the second exemplary embodiment.

In the present exemplary embodiment, as in the first and second exemplary embodiments, the electrically conductive members (the interconnections 2, electrode pads 3 and the joining material 4) may be formed of, for example, a sintered mass of fine metallic particles (fine particles of gold, silver or copper), or an electrically conductive paste or an electrically conductive ink inclusive of an organic-inorganic composite material containing electrically conductive fine particles dispersed therein. Those electrically conductive members are preferably formed of a material that may be cured or sintered at a temperature not higher than the melting point of the external electrode 6. Also, the electrically conductive members are preferably formed from the electrically conductive paste or ink, containing fine metallic particles with a particle size of the order of 20 nm or less, as a feedstock material.

Although the device(s) are mounted on only one substrate surface, the electronic devices may also be mounted in similar manner on both sides of the substrate 1.

As in the fourth exemplary embodiment, the device(s) may be mounted on a copper electrode pad 3b provided on the substrate 1 beforehand.

### (Meritorious Effect of the Sixth Exemplary Embodiment)

With the above-described package structure of the present exemplary embodiment, it is possible to change the device loading position, formulation of the devices loaded or the pitch of the external electrodes, without remodeling the substrate 1, as in the first exemplary embodiment described above. It is thus possible to manufacture a package with a high designing degree of freedom. In addition, since the number of the process steps or the volume of the wasted devices may be lesser than those with the background technique, such a product may be provided which is lower in cost and which is more benign to environment.

### Seventh Exemplary Embodiment

A package structure of a seventh exemplary embodiment of the present invention is now described.

### (Formulation of the Seventh Exemplary Embodiment)

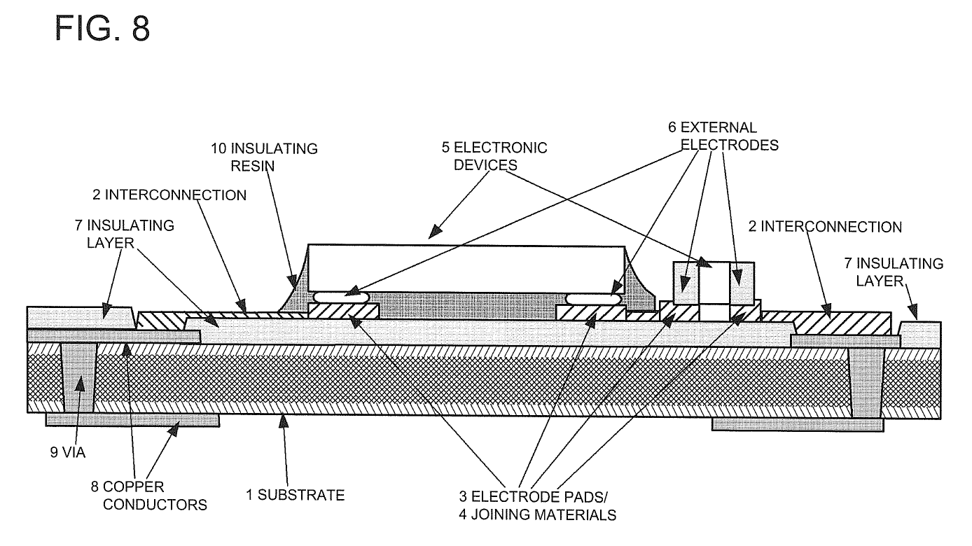

FIG. 8 depicts a cross-sectional view showing a basic illustrative form of a package structure in which a packaged device of the seventh exemplary embodiment of the present invention is partially protected by an insulating resin.

The package structure shown in FIG. 8 includes interconnections 2, electrode pads 3 and joining materials 4, all formed of the same material. The interconnections 2 are formed by extension from the electrically conductive layer (copper conductor (wiring) 8) provided beforehand on the surface of the substrate 1, and are formed on an insulating layer 7 also provided beforehand on the substrate surface. External electrodes 6 of electronic devices 5 are joined to the electrode pads 3 and to the joining materials 4. The present exemplary embodiment differs from the sixth exemplary embodiment in that a certain sort of the electronic device, such as BGA (Ball Grid Array) type device, is charged with an insulating resin to assure improved reliability.

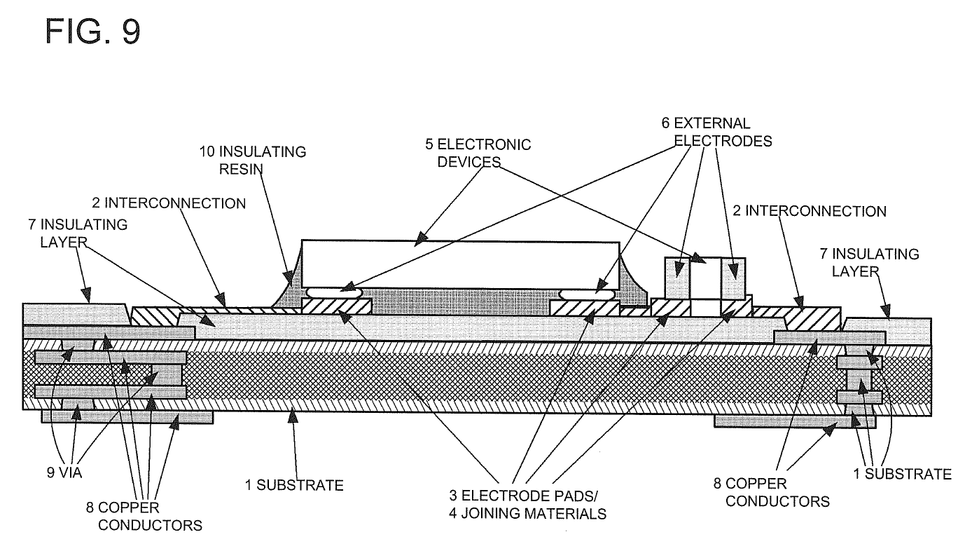

With the present exemplary embodiment, the substrate 1 is double-sided. The copper conductor (wiring) 8 on the front substrate side is connected to the copper conductor (wiring) 8 on the back substrate side through a via 9. As a matter of course, the substrate 1 is not necessarily double-sided, and may also be multi-layered, as shown in FIG. 9. It may also be single-sided, although not shown.

In FIGS. 8 and 9, the electrode pads 3 also serve as the joining materials 3 and vice versa. Alternatively, the joining materials 4 may be mounted as separate members on the electrode pads 3, as in the case of the second exemplary embodiment.

In the present exemplary embodiment, as in the first and second exemplary embodiments, the electrically conductive members (the interconnections 2, electrode pads 3 and the joining material 4) may be formed of, for example, a sintered mass of fine metallic particles (fine particles of gold, silver or copper), or an electrically conductive paste or an electrically conductive ink, inclusive of an organic-inorganic composite material in which are dispersed electrically conductive fine particles. Those electrically conductive members are preferably formed of a material that may be cured or sintered at a temperature not higher than the melting point of the external electrode 6. The electrically conductive members are preferably formed from the electrically conductive paste or ink containing fine metallic particles with a particle size of the order of 20 nm or less.

Although the electronic device(s) is mounted on only one substrate surface, the electronic devices may also be mounted in similar manner on both sides of the substrate 1.

As in the fourth exemplary embodiment, the device(s) may be mounted on a copper electrode pad 3b provided on the substrate 1 beforehand.

### (Meritorious Effect of the Seventh Exemplary Embodiment)

With the above-described package structure of the present exemplary embodiment, it is possible to change the device loading position, formulation of the devices loaded or the pitch of the external electrodes, without remodeling the substrate 1, as in the first exemplary embodiment described above. It is thus possible to manufacture a package with a high designing degree of freedom. In addition, since the number of the process steps or the volume of the wasted devices may be reduced as compared to those in the case of the background technique, such products may be provided which are lower in cost and which are more benign to environment.

Moreover, with the package structure of the present exemplary embodiment, in which a certain type of the electronic device 5, such as BGA (Ball Grid Array) type device, is charged (filled) with the insulating resin 10, such a package may be provided which is higher in reliability than with the packages obtained with the above-described exemplary embodiments.

### Eighth Exemplary Embodiment

A package structure of an eighth exemplary embodiment of the present invention is now described.

### (Formulation of Eighth Exemplary Embodiment)

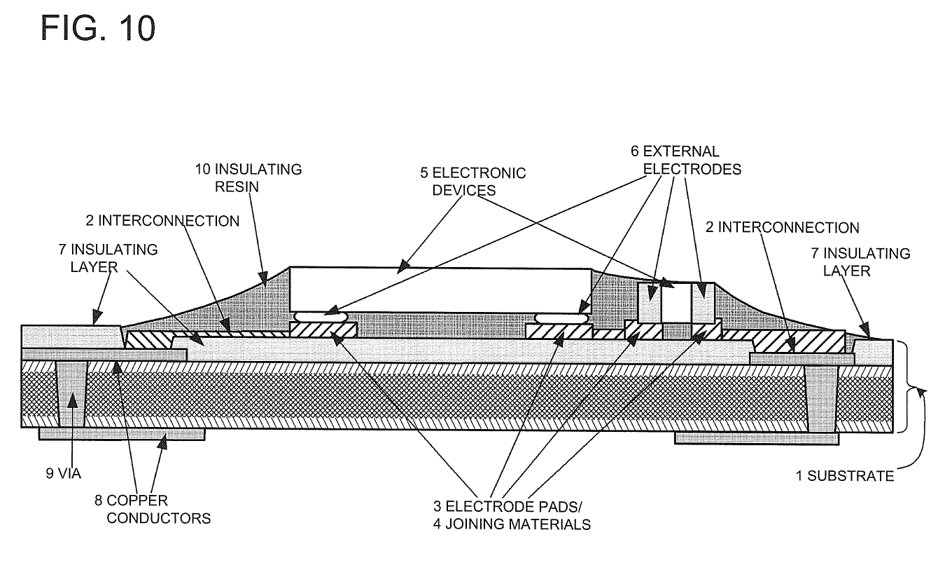

FIG. 10 depicts a cross-sectional view schematically showing a basic illustrative form of a package structure of an eighth exemplary embodiment of the present invention in which a part of a device mounted is protected with an insulating resin.

The package structure shown in FIG. 10 includes interconnections 2, electrode pads 3 and joining materials 4, all formed of the same material. The interconnections 2 are formed by extension from an electrically conductive layer (copper conductor (wiring) 8) provided beforehand on the surface of a substrate 1, and are formed on an insulating layer 7 equally provided preliminarily on the substrate surface. External electrodes 6 of electronic devices 5 are joined to the electrode pads 3 and to the joining materials 4. The present exemplary embodiment differs from the above-described sixth embodiment in that the electronic device 5 and the interconnections 2 are covered with an insulating resin 10 to assure improved reliability.

With the present exemplary embodiment, the substrate 1 is double-sided. The copper conductor (wiring) 8 on the front substrate side is connected to the copper conductor (wiring) 8 on the back substrate side through a via 9. As a matter of course, the substrate 1 is not necessarily double-sided and may also be multi-layered. It may also be single-sided, although not shown.

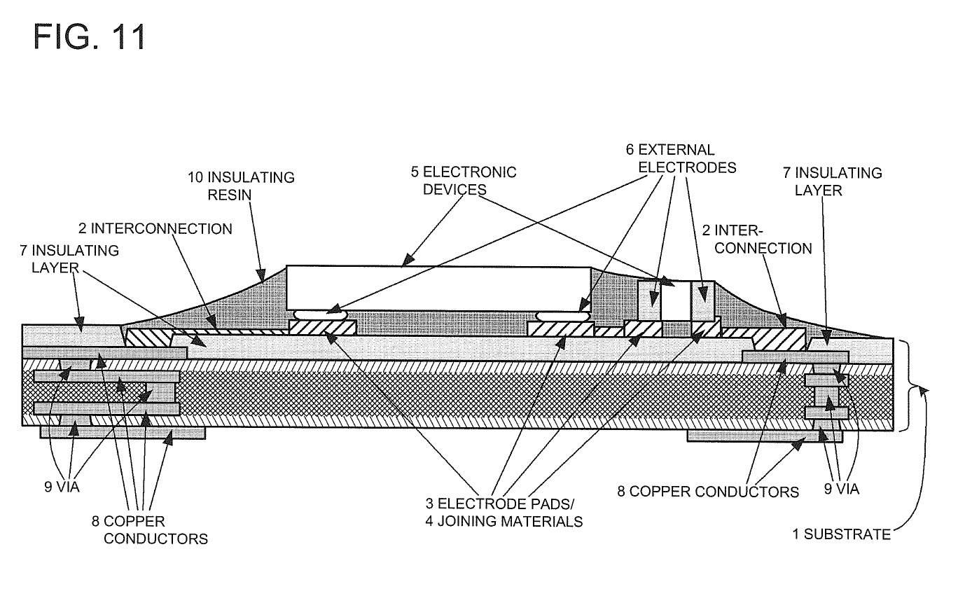

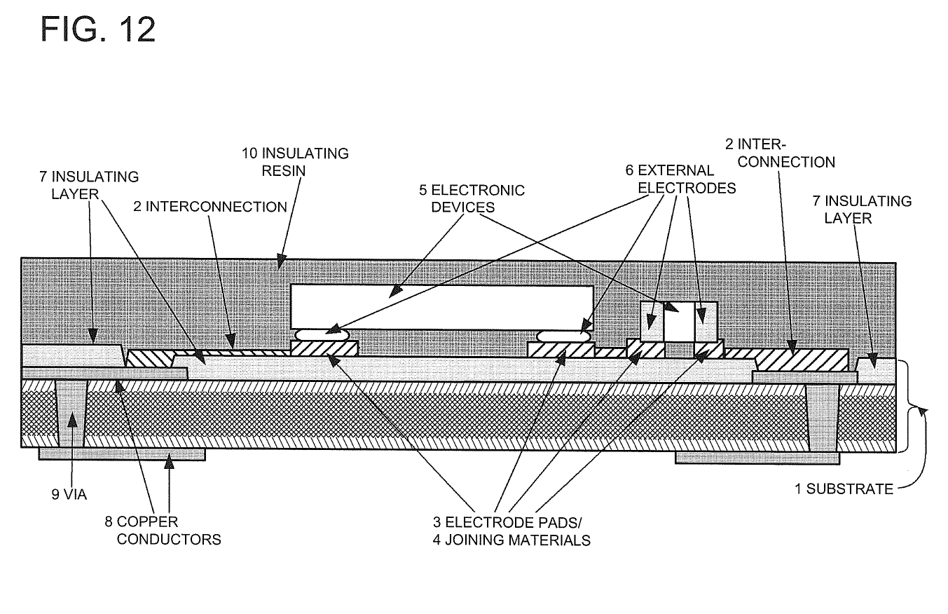

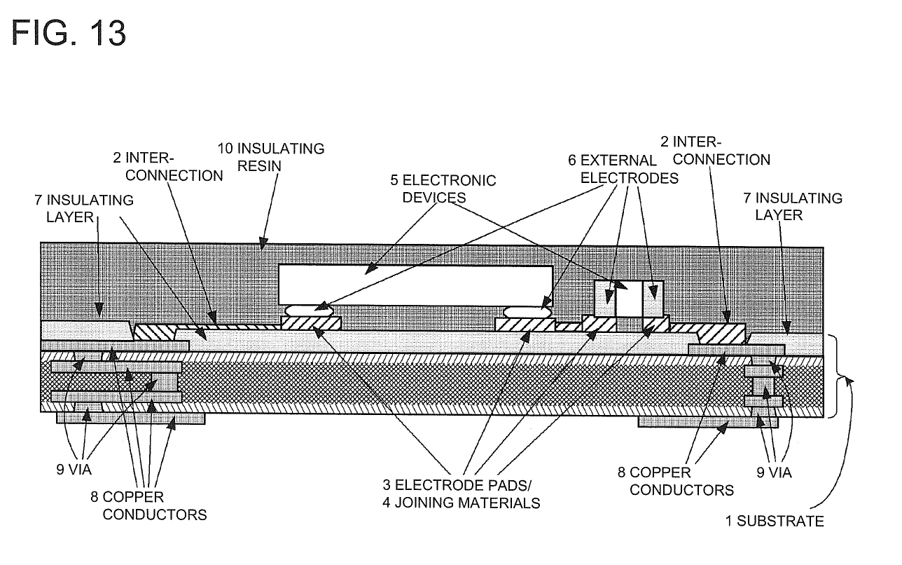

In FIGS. 10 and 11, the insulating resin 10 presents a concave/convex (irregular) surface. However, the present invention is not limited to this formulation and, as shown in FIGS. 12 and 13, the insulating resin 1 may be molded with a pattern so that the insulating resin 10 presents planar upper and lateral surfaces.

In FIGS. 10 and 11, the electrode pads 3 also serve as the joining materials 4 and vice versa, as in the first exemplary embodiment. Alternatively, the joining materials 4 may be mounted as separate members on the electrode pads 3, as in the second exemplary embodiment.

In the present exemplary embodiment, as in the first and second exemplary embodiments, the electrically conductive members (the interconnection 2, electrode pads 3 and the joining materials 4) may be formed of, for example, a sintered mass of fine metallic particles (fine particles of gold, silver or copper), or an electrically conductive paste or an electrically conductive ink inclusive of an organic-inorganic composite material in which electrically conductive fine particles are dispersed. Preferably, the electrically conductive members are formed of a material that may be cured or sintered at a temperature not higher than the melting point of the external electrode 6. The electrically conductive members are preferably formed from the electrically conductive paste or ink containing fine metallic particles with a particle size of the order of 20 nm or less.

Although the electronic device(s) is (are) mounted on only one substrate surface, the electronic devices may also be mounted in similar manner on both sides of the substrate 1.

As in the fourth exemplary embodiment, the above device(s) may be mounted on a copper electrode pad 3b provided on the substrate 1 beforehand.

### (Meritorious Effect of the Eighth Exemplary Embodiment)

With the above-described package structure of the present exemplary embodiment, it is possible to change the device loading position, formulation of the devices loaded or the pitch of the external electrodes, without remodeling the substrate 1, as in the first exemplary embodiment described above. It is thus possible to manufacture a package with a high designing degree of freedom. Moreover, since the number of the process steps or the volume of the wasted devices may be lesser than with the background technique, such package may be provided which is lower in cost and which is more benign to environment.

With the package structure of the present exemplary embodiment, in which the electronic device 5 and the interconnections 2 are covered with the insulating resin 10, such a package may be manufactured which is higher in reliability than the package of the above-described exemplary embodiments.

### Ninth Exemplary Embodiment

A package structure of a ninth exemplary embodiment of the present exemplary embodiment is now described.

### (Formulation of the Ninth Exemplary Embodiment)

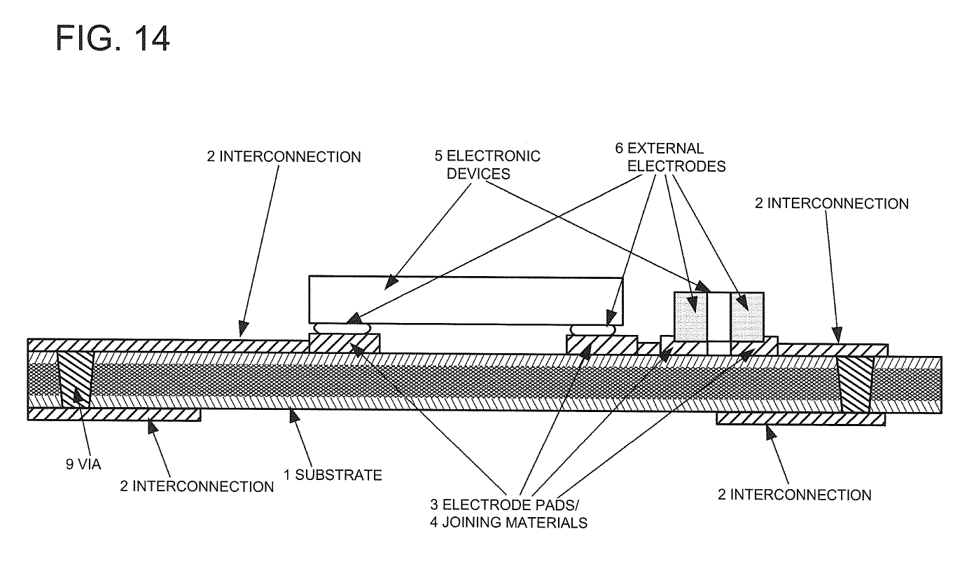

FIG. 14 depicts a cross-sectional view schematically showing an illustrative basic form of a package structure in case of forming interconnections on both substrate surfaces in accordance with the ninth exemplary embodiment of the present invention.

With the package structure, shown in FIG. 14, interconnections are formed on both the front and back surfaces of a substrate 1. The interconnections 2 on the front surface and those on the back surface are connected to each other with vias 9.

As a matter of course, part or entire of the electronic devices 5 and the interconnections 2 may be covered with the insulating resin 10, as described above.

In the present exemplary embodiment, shown in FIG. 14, the interconnections 2, electrode pads 3, joining material 4 and the vias 9 are formed of the same material. As in the first and second exemplary embodiments, the electrically conductive members (the interconnection 2, electrode pads 3 and the joining material 4) may be formed of, for example, a sintered mass of fine metallic particles (fine particles of gold, silver or copper), or an electrically conductive paste or an electrically conductive ink, including an organic-inorganic composite material in which are dispersed fine electrically conductive particles. Those electrically conductive members are preferably formed of a material that may be cured or sintered at a temperature not higher than the melting point of the external electrode 6.

It is noted that the vias 9 may be formed by boring holes in the substrate 1 beforehand and by filling these bores with the electrically conductive paste or ink. As stated above, the electrically conductive paste or ink, used as the electrically conductive members, preferably contains fine metallic particles with the particle size roughly of 20 nm or less.

In FIG. 14, the electrode pads 3 also serve as the joining materials 4 and vice versa, as in the first exemplary embodiment. Alternatively, the joining materials 4 may be provided as separate members on the electrode pads 3, as in the second exemplary embodiment.

Although the electronic device(s) are mounted on only one substrate surface, the electronic devices may also be mounted in similar manner on both sides of the substrate 1.

As in the fourth exemplary embodiment, the above device(s) may be mounted on a copper electrode pad 3b provided preliminarily on the substrate 1.

### (Meritorious Effect of the Eighth Exemplary Embodiment)

With the above-described package structure of the present exemplary embodiment, it is possible to change the device loading positions, formulation of the devices loaded or the pitch of the external electrodes, without remodeling the substrate 1, as in the first exemplary embodiment. It is thus possible to manufacture a package with a high designing degree of freedom. Moreover, since the number of the process steps or the volume of the wasted devices may be lesser than with the background technique, such package may be provided which is lower in cost and which is more benign to environment.

### Tenth Exemplary Embodiment

A package structure according to a tenth exemplary embodiment of the present invention is now described.

### (Formulation of the Tenth Exemplary Embodiment)

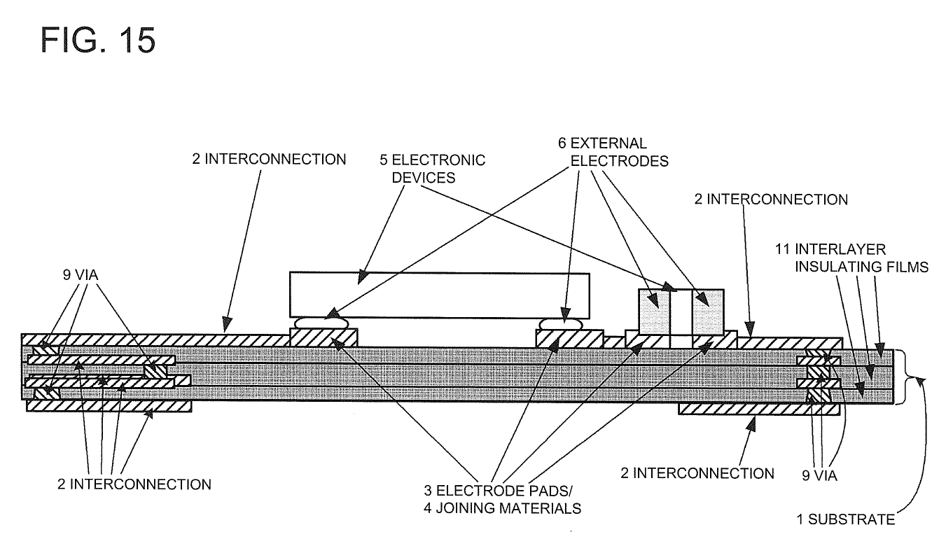

FIG. 15 depicts a cross-sectional view schematically showing an illustrative basic form of a package structure, in which multi-layered interconnections are to be formed, according to the tenth exemplary embodiment of the present invention is now described.

With the package structure, shown in FIG. 15, interconnections 2 are formed in layers on the front side, back side and on an inner layer or layers of the substrate 1. The interconnections are insulated from one another by interlayer insulating layers 11, and are interconnected by vias 9. Electronic devices 5 are mounted on the multi-layer substrate. As a matter of course, part or all of the interconnections 2 or the devices may be covered with an insulating resin 10.

With the present exemplary embodiment of FIG. 15, the interconnections 2, electrode pads 3, joining material 4 and the vias 9 are formed of the same material. As in the first and second exemplary embodiments, the electrically conductive members (the interconnections 2, electrode pads 3 and the joining material 4) may be formed of, for example, a sintered mass of fine metallic particles (fine particles of gold, silver or copper), or an electrically conductive paste or an electrically conductive ink, including an organic-inorganic composite material in which are dispersed fine electrically conductive particles. Those electrically conductive members are preferably formed of a material that may be cured or sintered at a temperature not higher than the melting point of the external electrode 6.

It is noted that the vias 9 may be formed by boring holes in the substrate 1 beforehand. These bores are filled with the electrically conductive paste or ink. The electrically conductive paste or ink, used as the electrically conductive members, preferably contains fine metallic particles with the particle size roughly of 20 nm or less, as stated above.

In FIG. 15, the electrode pads 3 also serve as the joining materials 4 and vice versa, as in the first exemplary embodiment. Alternatively, the joining materials 4 may be provided as separate members on the electrode pads 3, as in the second exemplary embodiment.

Although the electronic device(s) are mounted on only one substrate surface, the electronic devices may also be mounted in similar manner on both sides of the substrate 1.

As in the fourth exemplary embodiment, the above device(s) may be mounted on a copper electrode pad 3b provided on the substrate 1 preliminarily.

### (Meritorious Effect of the Tenth Exemplary Embodiment)

With the above-described package structure of the present exemplary embodiment, it is possible to change the device loading positions, formulation of the devices loaded or the pitch of the external electrodes, without remodeling the substrate 1, as in the first exemplary embodiment. It is thus possible to manufacture a package with a high designing degree of freedom. Moreover, since the number of the process steps or the volume of the wasted devices may be lesser than those with the background technique, such package may be provided which is lower in cost and which is more benign to environment.

### Eleventh Exemplary Embodiment

The method for manufacturing a package according to an eleventh exemplary embodiment of the present invention is now described.

The method for manufacturing a package of the present exemplary embodiment includes a preparation step of providing a substrate 1, on at least one surface of which interconnections 2 may be formed, as described above, and an interconnection step of providing the interconnections 2, electrode pads 3 and joining materials 4. The method also includes a mounting step of mounting an electronic device(s) on the electrode pads 3 that form part of the interconnections 2.

With the package manufacturing method of the present exemplary embodiment, the interconnections 2, electrode pads 3 and the joining materials 4 are provided in the preparation step on the substrate 1 that allows providing for interconnection thereon. An electronic device(s) is then loaded in position and joined by a packaging step to complete a package. With the present exemplary embodiment, it is possible to manufacture a package structure of the above-described first exemplary embodiment.

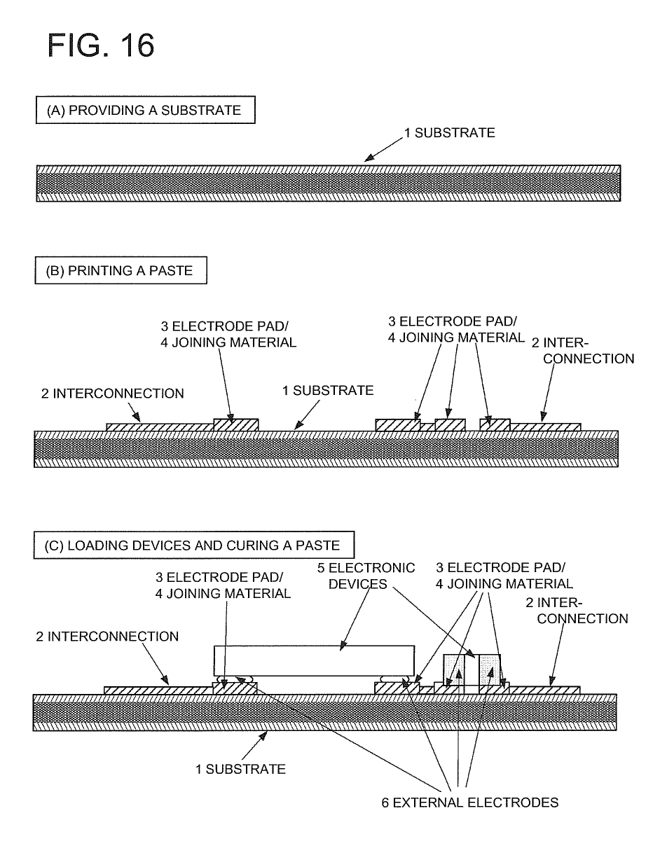

FIG. 16 depicts a cross-sectional view schematically showing a basic example method for manufacturing a package for electronic device(s) according to the present exemplary embodiment. The present method is now described step-by-step by referring to FIG. 16 as necessary.

First, in the preparation step, a substrate 1, on at least one surface of which may be formed interconnections 2 and electrode pads 3, is provided ((A) of FIG. 16). There is no limitation to the type of the material of the substrate 1 provided that the substrate may be formed of the material that may form the interconnections 2 thereon. Thus, glass epoxy or polyimide, for example, may be used.

In the next following interconnection step, an electrode pad 3-a joining material 4, used for joining the interconnections 2 and the external electrode 6 of the electronic device 5, is provided ((B) of FIG. 16).

These electrically conductive members (interconnection 2 and electrode pad 3/joining material 4), may be provided by printing the electrically conductive paste or the electrically conductive ink composed of the resin-metal filler combination. There is no limitation to the particular material used for the electrically conductive paste or ink on the condition that these possess desired specific electrical conductivity, printability, curing characteristic and reliability. The electrically conductive paste or ink, containing fine metal particles, or the electrically conductive ink, containing fine metallic particles, may be used as a feedstock material for the electrically conductive paste or ink. To achieve a high density package, it is preferred to do efforts to narrow down the pitch of the respective interconnections.

It is also preferred to do efforts to reduce the resistance of the interconnections 2. To this end, the electrically conductive paste or ink, containing fine metal particles with the particle size of the order of 20 nm or less and preferably fine metallic particles with the particle size of the order of 15 nm or less, are to be used as the electrically conductive members. Since particles of a metal material with a particle size of the order of tens of nms or less are liable to be fused together at lower temperatures, there is a good prospect that use of fillers in the form of fine particles leads to improved printability and to improved electrical conductivity.

In case the interconnection part is formed from the above-described electrically conductive paste or ink as a feedstock material, there is no limitation to the applying methods as far as it is a method that gives a preset pattern or shape. The electrically conductive paste or ink may be applied by coating to give a preset pattern on the surface of the substrate 1 by a printing method that uses a mask, such as screen printing, an ink jet method, or by a dispensing method that uses a dispenser for coating.

Then, in the mounting step, the electronic device 5 is mounted on the electrode pad 3 so that the external electrode 6 of the electronic device 5 is contacted with the electrode pad 3 while as yet the electrically conductive paste or ink is in the uncured state. The electrically conductive paste or ink, thus applied, is then heated to be cured, which allows simultaneous formation of the interconnections 2 and joins the electronic device 5 ((C) of FIG. 16).

In case the fine metallic particles with a size roughly of 20 nm or less are contained in the electrically conductive members, these fine metallic particles may be sintered at a relatively lower temperature (roughly of 150 to 250° C.), and hence the electrical conductivity may be improved further with sintering. It is the resin contained in the paste or the ink that may develop the joining force of the electronic device 5 loaded. However, the joining may also be by the metal material of the external electrode 6 of the electronic device 5 and the metallic fillers in the paste or ink becoming fused together or otherwise producing an anchoring effect. The joining force may also be developed by both the resin material and the metal material.

There is no particular limitation to the resin material of the electrically conductive paste or ink, on the condition that the resin used has strength sufficient to join the electronic device to it in stability. Examples of the resin may include epoxy resin, polyester resin, phenolic resin, urethane resin and the acrylic resin, either singly or in combination. However, from the perspective of the joining strength, an epoxy resin is preferably contained at least as a part of the resin material.

In this case, such a material that may be cured or sintered at a temperature not higher than the melting point of the external electrode 6, and the heating process that is matched to this temperature condition, are preferably used.

With the electrically conductive paste, it is customary to keep it for a preset time at a preset temperature for curing. In case the particle size of the fine metal particles is roughly of 20 nm or less, the material may be sintered in a short time provided that the temperature is roughly of 200 to 300° C. Thus, paste curing and the sintering of the fine metal particles at higher temperature within a short time may be achieved using a heating hysteresis similar to that used for heating by a reflow furnace in the course of soldering.

However, in such case, it is preferred to use a material that may be cured or sintered at a temperature not higher than the melting point of the external electrode 6 and a heating profile that allows such curing or sintering.

The present exemplary embodiment shows a case where the electronic device(s) are mounted only on one substrate side. The electronic devices may be mounted in similar manner on both sides of the substrate 1 as well.

The resin material of the electrode pad 3 may be made thicker in thickness than the material of the interconnection 2 in mounting the interconnection and the electrode pad on the substrate 1.

### [Meritorious Effect of the Eleventh Exemplary Embodiment]

With the above-described package structure of the present exemplary embodiment, it is possible to change the device loading position, formulation of the devices loaded or the pitch of the external electrodes, as in the first exemplary embodiment described above. It is thus possible to manufacture a package with a high designing degree of freedom. In addition, since the number of the process steps or the volume of the wasted devices may be lesser than in the case of the background technique, it is possible to provide a product lower in cost and which is more benign to environment.

### Twelfth Exemplary Embodiment

A method for manufacturing a package according to a twelfth exemplary embodiment of the present invention is now described.

In the package manufacturing method of the present exemplary embodiment, an interconnection 2 and an electrode pad 3 are provided, in a preparation step, on a substrate 1 on which it is possible to form the interconnection 2. After this readying step, a mounting step of providing the joining material 4 and mounting/joining the device(s) is carried out to complete a package. With the present exemplary embodiment, it is possible to manufacture the package structure of the above-described second exemplary embodiment.

FIG. 17 depicts a cross-sectional view schematically showing a basic illustrative form of a method for manufacturing a package for electronic device(s) of the present exemplary embodiment. The present manufacturing method is now described step-by-step with reference to FIG. 17 as necessary.

First, as a preparation step, a substrate 1, on at least one side of which may be formed an interconnection 2 and an electrode pad 3, is provided ((A) of FIG. 17). There is no limitation to the particular material of the substrate 1, provided that the interconnection 2 may be formed thereon. Thus, glass epoxy or polyimide, for example, may be used.

In the next interconnection step, the interconnection 2 and the electrode pad 3 for joining the interconnection 2 to an external electrode 6 of an electronic device 5 is provided ((B) of FIG. 17).

These electrically conductive members (interconnection 2 and the electrode pad 3) may be provided by printing the electrically conductive paste or the electrically conductive ink made up of a resin material and metallic fillers. After printing the electrically conductive members on the substrate 1 to a desired pattern, the resulting assembly is heated to be cured to form an interconnection pattern.

Then, in a mounting step, an electrically conductive paste or ink of the same pattern as the interconnection pattern prepared in the previous step is printed, as a joining material 4, on the electrode pad 3 of the above interconnection pattern ((C) of FIG. 17). The electronic device 5 then is mounted so that the external electrode 6 of the device 5 is contacted with the printed paste or ink. The electrically conductive paste or ink, thus applied, is then cured on heating to complete a package ((D) of FIG. 17).

In case fine metallic particles having a particle size roughly of 20 nm or less are contained in the electrically conductive members, these fine metallic particles may be sintered at lower temperatures (ca. of 150 to 250° C.). Thus, with sintering, the electrical conductivity may be improved further. It is the resin contained in the paste or the ink that may develop the joining force of the electronic device(s) 5 loaded. However, the joining may also be by the metal material of the external electrode 6 of the electronic device 5 and the metallic fillers in the paste or ink becoming fused together or otherwise producing an anchoring effect. The joining force may also be developed by both the resin material and the metal material.

There is no limitation to the electrically conductive paste or the electrically conductive ink on the condition that such paste or ink has desired specific electrical conductivity, printability, curing characteristic and reliability. As regards this point, the present method is similar to the package manufacturing method of the above-described eleventh exemplary embodiment.

The present method is also similar to the package manufacturing method of the above-described eleventh exemplary embodiment in that it is preferred to use a material that may be cured or sintered at a temperature not higher than the melting point of the external electrode 6.

There is no particular limitation to the paste applying method, as with the package manufacturing method of the above-described eleventh exemplary embodiment, on the condition that the desired pattern of the interconnection may be produced.

The present exemplary embodiment shows a case where the electronic device(s) are mounted only on one substrate side. The electronic devices may also be mounted in a similar manner on both sides of the substrate 1.

### (Meritorious Effect of the Twelfth Exemplary Embodiment)

With the above-described package structure of the present exemplary embodiment, it is possible to change the device loading position, formulation of the devices loaded or the pitch of the external electrodes, as in the eleventh exemplary embodiment described above. It is thus possible to manufacture a package with a high designing degree of freedom. In addition, since the number of the process steps or the volume of the wasted devices may be lesser than the case with the background technique, it is possible to provide a product lower in cost and which is more benign to environment.

### Thirteenth Exemplary Embodiment

A method for manufacturing a package according to a thirteenth exemplary embodiment of the present invention is now described.

With the package manufacturing method of the present exemplary embodiment, a package is completed by a preparation step, an interconnection step and a mounting step. In the preparation step, an electrically conductive layer (copper conductor/wiring) 8, which may also include a land, is formed beforehand on the substrate, and an area is reserved in a portion of the substrate in which to form the interconnection 2. In the interconnection step, the interconnections 2, electrode pad 3 and the joining material 4 are delivered to the printable area of the substrate 1. In the mounting step, an electronic device is loaded in position and joined in situ. With the present exemplary embodiment, it is possible to produce the package structure according to e.g. the fourth exemplary embodiment described above.

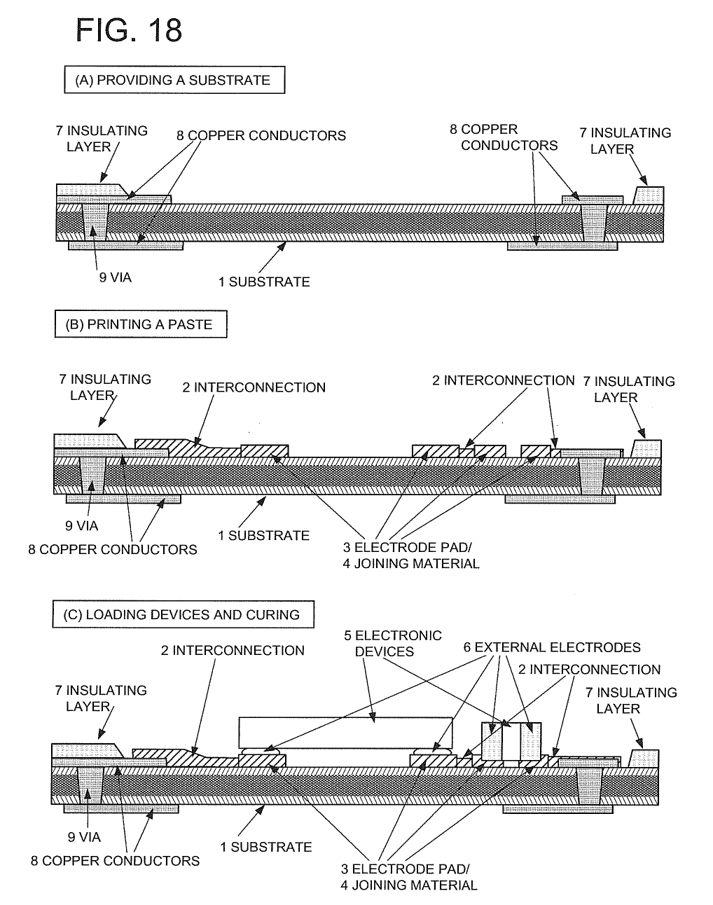

FIG. 18 depicts a cross-sectional view schematically showing a method for manufacturing a package of an electronic device according to the present exemplary embodiment. The present manufacturing method is now described step-by-step with reference to FIG. 18 as necessary.

First, in the preparation step, an electrically conductive layer (copper conductor) 8, which may also include a land, is formed beforehand on a substrate 1, and an area is reserved in a portion of the substrate in which to form the interconnection 2 ((A) of FIG. 18). There is no limitation to the substrate 1 as far as the interconnection 2 may be formed thereon. Thus, the substrate may be formed of, for example, glass epoxy or polyimide. Although a copper conductor 8 is given as an example, it may be formed of any other suitable materials, provided that plating may also be formed thereon.

In the next interconnection step, the electrode pad 3 and the joining material 4 for joining the interconnection 2 and the external electrode 6 of the electronic device 5 is provided on the interconnection forming area of the substrate 1 provided in the previous step (FIG. 18(B)). The electrode pad 3 and the joining material 4 are of the same material. The interconnection 2 may have its one end connected to the copper conductor 8 that has already been formed in the previous step. The electrically conductive members (interconnection 2 and electrode pad 3) may be provided by printing the electrically conductive paste or ink composed of the combination of resin and metallic fillers.

Then, in the mounting step, the electronic device 5 is loaded on the electrode pad 3, provided in the previous step, so that the external electrode 6 of the electronic device thus loaded is contacted with the electrode pad 3 of the interconnection pattern, as provided in the previous step, in a state where the electrically conductive paste or ink is in a non-cured state. The electrically conductive paste or ink supplied is cured on heating to complete a package ((C) of FIG. 18).

As described above, in case fine metallic particles having a particle size of (about) 20 nm or less are contained in the electrically conductive members, these fine metallic particles may be sintered at lower temperatures (ca. ranging 150 to 250° C.). Thus, with sintering, the electrical conductivity may be improved further. It is the resin contained in the paste or the ink that may develop the joining force of the electronic device(s) 5 loaded. However, the joining may also be by the metal material of the external electrode 6 of the electronic device 5 and the metallic fillers in the paste or ink becoming fused together or otherwise producing an anchoring effect. The joining force may also be developed by both the resin material and the metal material.

There is no limitation to the electrically conductive paste or the electrically conductive ink as far as paste or ink has desired electrical conductivity, printability, curing characteristic and reliability. As regards this point, the present method is similar to the package manufacturing method of the above-described eleventh exemplary embodiment.

The present method is also similar to the package manufacturing method of the above-described eleventh exemplary embodiment in such respect that, for the electrically conductive paste or ink, it is desirable to use a material that may be cured or sintered at a temperature not higher than the melting point of the external electrode 6. Such heating process that is matched to this temperature condition is also preferably used.

There is also no particular limitation to the paste applying (coating) method, as with the package manufacturing method of the above-described eleventh exemplary embodiment, as far as the desired pattern of the interconnection may be produced.

The present exemplary embodiment shows a case where the electronic device is mounted only on one substrate side. The electronic devices may be mounted in similar manner on both sides of the substrate 1 as well.

The electronic device(s) 5 may also be mounted on the copper electrode pads 3b provided beforehand on the substrate, as stated previously with reference to (b) of FIG. 4. It should be noted that the electrically conductive resin or the electrically conductive film as the joining material 4 is provided in a lump (or all together at once) onto the copper electrode pads 3b so that the joining material 4 is cured along with the interconnection 2 to form a bond. However, a solder or an electrically conductive resin may also be delivered separately to form the bond.

### (Meritorious Effect of the Thirteenth Exemplary Embodiment)

With the above-described package structure of the present exemplary embodiment, it is possible to change the device loading position, formulation of the device(s) loaded or the pitch of the external electrodes, as in the eleventh exemplary embodiment described above. It is thus possible to manufacture a package with a high designing degree of freedom. In addition, since the number of the process steps or the volume of the wasted devices may be lesser than with the background technique, it is possible to provide a product lower in cost and which is more benign to environment.

### Fourteenth Exemplary Embodiment

A method for manufacturing a package according to a fourteenth exemplary embodiment of the present invention is now described.

With the package manufacturing method of the present exemplary embodiment, a package is completed through a preparation step, an interconnection step and a mounting step. In the preparation step, an electrically conductive layer (copper conductor) 8, which may also include a land, is formed beforehand on the substrate, and an area is reserved in a portion of the substrate in which to form the interconnection 2. In the interconnection step, interconnections 2, electrode pad 3 and a joining material 4 are furnished to a printable area of the substrate 1. In the mounting step, an electronic device is loaded in position and joined in situ. With the present exemplary embodiment, it is possible to produce the package structure according to e.g., the third exemplary embodiment described above.

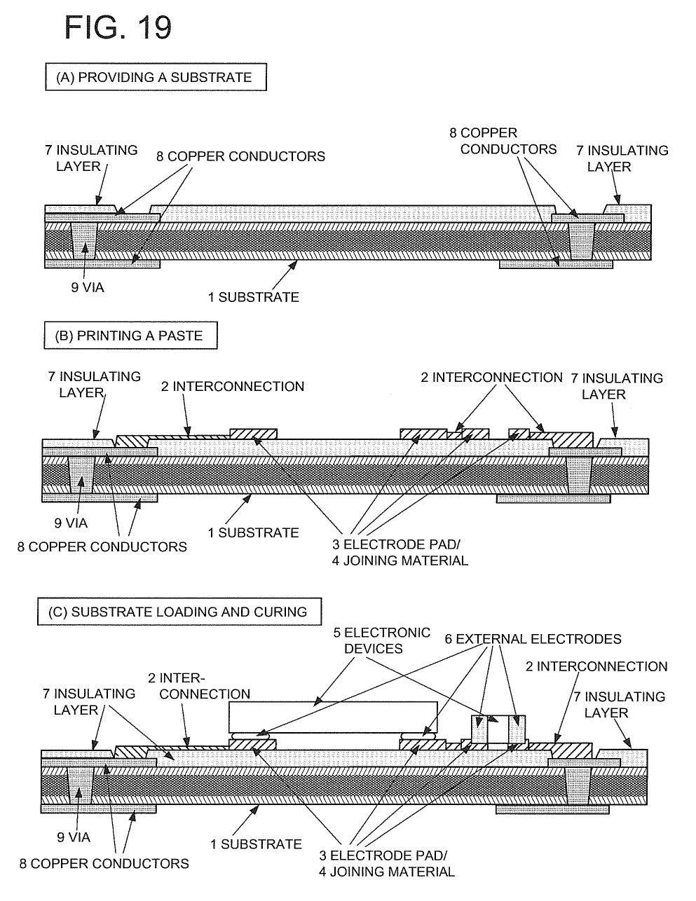

FIG. 19 depicts a cross-sectional view schematically showing a method for manufacturing a package of an electronic device according to the present exemplary embodiment. The present manufacturing method is now described step-by-step with reference to FIG. 19 as necessary.

In the preparation step, a substrate 1, on at least one surface of which an electrically conductive layer (copper conductor) 8 has been formed, is provided. To protect this copper conductor 8, the substrate surface except a fractional portion is covered with an insulating layer 7. This fractional portion serves as an area in which the interconnection 2 is to be formed ((A) of FIG. 19). There is no limitation to the particular material of the substrate 1 provided that the interconnections 2 may be formed thereon. Thus, for example, glass epoxy or polyimide may be used. Although the copper conductor 8 is given as an example in the present exemplary embodiment, the conductor may also be of any other suitable material. The interconnection 2 may also be plated, if desired.

In the next interconnection step, the electrode pad 3 and the joining material 4 for joining the interconnection 2 and the external electrode 6 of the electronic device 5 together are provided in the interconnection forming area of the substrate 1 provided in the previous step ((B) of FIG. 19). The electrode pad 3 and the joining material 4 are of the same material. The interconnection 2 may have its one end connected to the copper conductor 8 which has already been formed in the previous step. The electrically conductive members (interconnection 2 and electrode pad 3) may be provided by printing the electrically conductive paste or ink composed of the combination of the resin and metallic fillers.

Then, in the mounting step, the electronic device 5 is loaded on the electrode pad of the interconnection pattern, provided in the previous step, so that the external electrode 6 of the electronic device 5 thus loaded is contacted with the electrode pad 3. The electrically conductive paste or ink applied is then cured on heating to complete a package ((C) of FIG. 19).

As described above, fine metallic particles having a particle size roughly of 20 nm or less may be contained in the electrically conductive members. These fine metallic particles may be sintered at relatively lower temperatures (ca. ranging 150 to 250° C.). Thus, with sintering, the specific electrical conductivity may be improved further. It is the resin contained in the paste or the ink that may develop the joining force of the electronic device(s) 5 loaded. However, the joining may also be by the metal material of the external electrode 6 of the electronic device 5 and the metallic fillers in the paste or ink becoming fused together or otherwise producing an anchoring effect. The joining force may also be developed by both the resin material and the metal material.

There is no limitation to the electrically conductive paste or the electrically conductive ink on the condition that such paste or ink has desired specific electrical conductivity, printability, curing characteristic and reliability. As regards this respect, the present method is similar to the package manufacturing method of the above-described eleventh exemplary embodiment.

The present method is also similar to the package manufacturing method of the above-described eleventh exemplary embodiment in such respect that, for the electrically conductive paste or ink, it is desirable to use a material that may be cured or sintered at a temperature not higher than the melting point of the external electrode 6. Such heating process that is matched to this temperature condition is preferably used.

There is also no particular limitation to the paste applying method, as with the above-described eleventh exemplary embodiment, on the condition that the paste applying method used allows a desired pattern to be produced.

The present exemplary embodiment shows a case where the electronic device(s) are mounted only on one substrate side. The electronic devices may be mounted in similar manner on both sides of the substrate 1 as well.

The electronic device 5 may also be mounted on a copper electrode pad 3b provided beforehand on the substrate, as with the package manufacturing method of the above-described thirteenth exemplary embodiment.

### (Meritorious Effect of the Fourteenth Exemplary Embodiment)

With the above-described package structure of the present exemplary embodiment, it is possible to change the device loading position, formulation of the electronic device loaded or the pitch of the external electrodes, as in the first exemplary embodiment described above. It is thus possible to manufacture a package with a high designing degree of freedom. In addition, since the number of the process steps or the volume of the wasted devices may be lesser than with the background technique, it is possible to provide a product lower in cost and which is more benign to environment.

### Fifteenth Exemplary Embodiment

A method for manufacturing a package according to a fifteenth exemplary embodiment of the present invention is now described.

With the package manufacturing method of the present exemplary embodiment, a package is completed through a preparation step, a first interconnection step, a second interconnection step, and a mounting step. In the preparation step, there is provided a substrate 1, on each of the front and back surfaces of which has been provided an area that allows formation of an interconnection 2. A via 9 is formed on a stage (releasable layer) 12 for establishing electrical conduction across the front and back substrate surfaces. In the first interconnection step, the interconnection 2 and a via charging member are provided in a printable area on one surface of the substrate 1. In the second interconnection step, the interconnection members, that is, the interconnections 2, electrode pads 3 and the joining materials 4, are supplied to a printable area on the opposite substrate surface. The next following mounting step loads and joins an electronic device. The present exemplary embodiment allows manufacturing e.g. a package structure according to the above-described ninth exemplary embodiment.

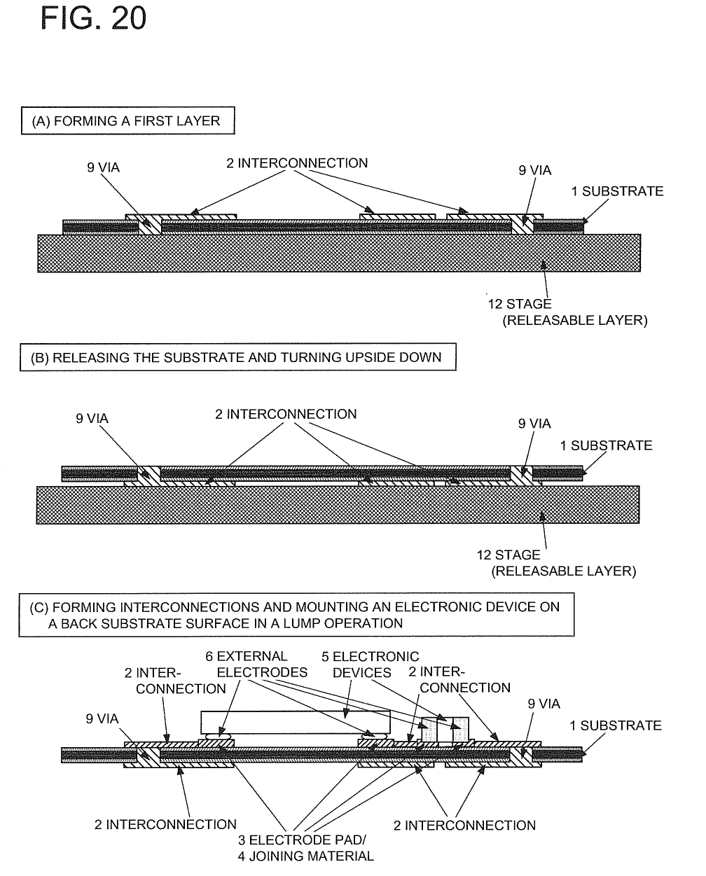

FIG. 20 depicts a cross-sectional view schematically showing a basic example method for manufacturing a package of an electronic device(s) according to the present exemplary embodiment. The present manufacturing method is now described step-by-step with reference to FIG. 20 as necessary.

First, in the substrate readying step and in the first interconnection step, there is provided a substrate 1 on each side of which is formed an area that allows formation of the interconnections 2. Then, on a release stage (releasable layer) 12, there is bored a hole that serves as a via 9 for establishing electrical conduction across the front and back substrate sides. The via is then charged, at the same time as the interconnections 2 are formed, as a lump operation of printing and curing ((A) of FIG. 20). There is no limitation to the material of the substrate 1 provided that the material used allows the interconnections 2 to be formed thereon. That is, glass epoxy or polyimide may be used as the material for the substrate 1.

In the next following second interconnection step, the substrate 1, having the interconnections 2 formed on its one side by the previous step, is turned upside-down ((B) of FIG. 20). The electrode pads 3 and the joining materials 4 are then provided to an interconnection forming area on the opposite substrate surface for joining the interconnections 2 and the external electrodes 6 of the electronic device 5 to each other. The electrode pads 3 and the joining materials 4 are provided as the same material. The electrically conductive members (interconnections 2 and the electrode pads 3) may be provided by printing an electrically conductive paste or ink composed of the combination of a resin and metallic fillers.

Then, in the mounting step, an electronic device 5 is loaded on the electrode pad 5 of the interconnection pattern provided in the previous step so that an external electrode 6 of the electronic device 5 is contacted with the electrode pad. The electrically conductive paste or ink, thus applied, is then cured on heating to complete a package ((C) of FIG. 20).

As described above, in case fine metallic particles having a particle size roughly of 20 nm or less are contained in the electrically conductive members, these fine metallic particles may be sintered at relatively low temperatures (ca. ranging 150 to 250° C.). Thus, with sintering, the electrical conductivity may be improved further. It is the resin contained in the paste or the ink that produces the joining force of the electronic device(s) 5 loaded. However, the joining may also be by the metal material of the external electrode 6 of the electronic device 5 and the metallic fillers in the paste or ink becoming fused together or otherwise producing an anchoring effect. The joining force may also be developed by both the resin material and the metal material.

There is no limitation to the electrically conductive paste or the electrically conductive ink on the condition that such paste or ink has desired electrical conductivity, printability, curing characteristic and reliability. As regards this respect, the present method is similar to the package manufacturing method of the above-described eleventh exemplary embodiment.

The present method is also similar to the package manufacturing method of the above-described eleventh exemplary embodiment in such respect that, for the electrically conductive paste or ink, it is preferred to use a material that may be cured or sintered at a temperature not higher than the melting point of the external electrode 6. Such heating process that is matched to this temperature condition is also preferably used.

There is also no particular limitation to the paste applying method, as with the above-described eleventh exemplary embodiment, as far as the paste applying method used allows the desired pattern of the interconnection to be produced.

The present exemplary embodiment shows a case where the electronic device(s) are mounted only on one substrate side. The electronic devices may be mounted in similar manner on both sides of the substrate 1 as well.

### (Meritorious Effect of the Fifteenth Exemplary Embodiment)

With the above-described package structure of the present exemplary embodiment, it is possible to change the device loading position, formulation of the device loaded or the pitch of the external electrodes, as in the eleventh exemplary embodiment described above. It is thus possible to manufacture a package with a high designing degree of freedom. In addition, since the number of the process steps or the volume of the wasted devices may be lesser than with the background technique, it is possible to provide a product lower in cost and which is more benign to environment.

### Sixteenth Exemplary Embodiment

A method for manufacturing a package according to a sixteenth exemplary embodiment of the present invention is now described.

With the package manufacturing method of the present exemplary embodiment, a package is completed through a preparation step, a first interconnection step, a multi-layering step, an uppermost layer interconnection step, a mounting step and a back side interconnection step. In the preparation step, there is provided an interlayer insulating film 11, on each of the front and back surfaces of which has been provided an area that allows the formation of an interconnection 2. A via 9 is also formed in this step in the interlayer insulating film for establishing electrical conduction across its front and back surfaces. In the first interconnection step, the interconnection 2 and a via charging member are provided in a printable area on one surface of the substrate 1. In the multi-layering step, an interlayer insulating film 11 and an interconnection layer are additionally provided to form a multi-layer substrate. In the uppermost layer interconnection step, an interconnection member is provided on the printable portion on the uppermost substrate surface to provide the interconnections 2, electrode pads 3 and the joining materials 4. In the mounting step, the electronic device is loaded and joined in situ. In the back side interconnection step, the interconnections 2 are formed on the back surface. With the present exemplary embodiment, the package structure according to e.g., the above-described tenth exemplary embodiment may be produced.

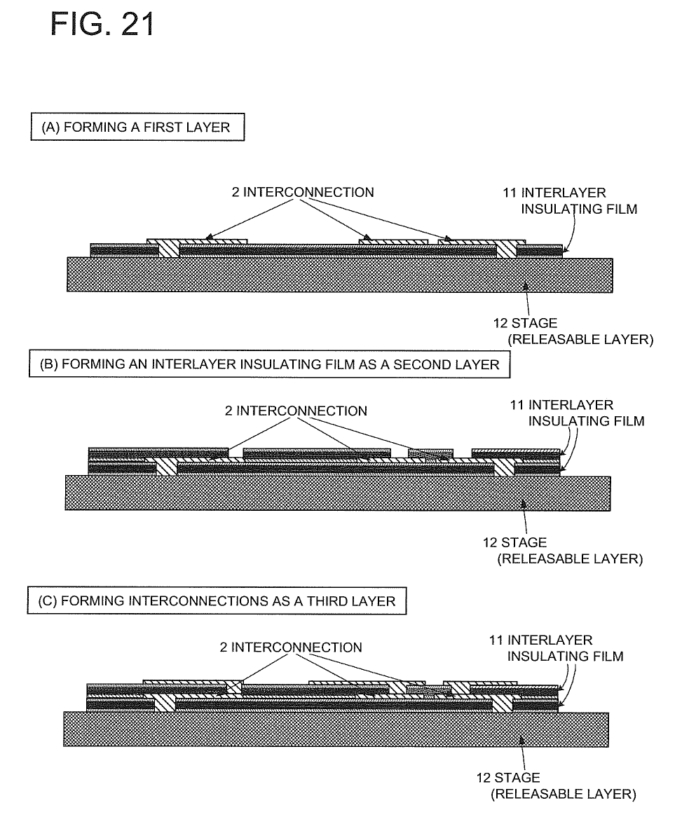

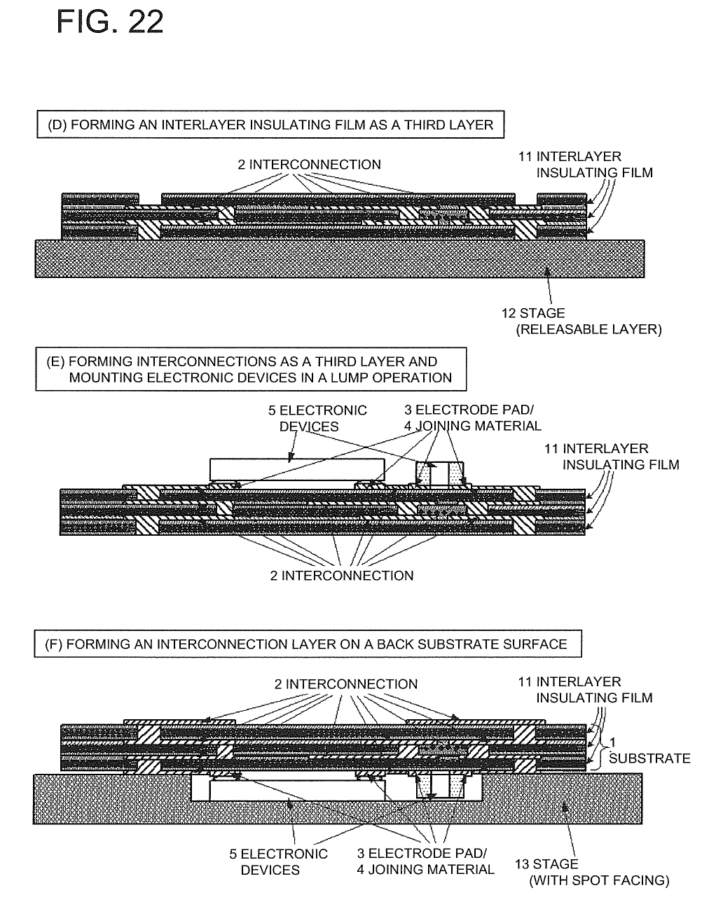

FIGS. 21 and 22 depict cross-sectional views schematically showing a basic example method for manufacturing a package for an electronic device(s) according to the present exemplary embodiment. The present method is now described step-by-step with reference to FIGS. 21 and 22 as necessary.

First, in the preparation step and the first interconnection step, there is provided then interlayer insulating film 11, on each surface of which has been formed an area for forming the interconnection. Then, on a release stage (releasable layer) 12, there is bored a hole that serves as a via for establishing electrical conduction across the front and back sides. The via is then charged, at the same time as the interconnections 2 are formed, as a lumped operation of printing and curing ((A) of FIG. 21). There is no limitation to the material of the substrate 1 provided that the material used allows the interconnections 2 to be formed thereon. That is, glass epoxy or polyimide may be used as the material for the substrate 1.

On the interlayer insulating film 11, now carrying the interconnections 2, another insulating film 11 is further formed, and vias are formed in similar manner for establishing electrical connection across the interconnections 2 and an underlying layer. The above process steps are carried out a number of times to provide multi-layered interconnections 2 ((B) and (C) of FIG. 21, and (D) of FIG. 22).

In the uppermost layer interconnection process, the electrode pads 3 and the joining materials 4 are then provided onto the interconnection forming area on the uppermost layer to join the interconnections 2 and the external electrodes 6 of the electronic devices 5 to each other. The electrode pads 3 and the joining materials 4 are provided as the same material. The electrically conductive members (interconnections 2 and the electrode pads 3) may be provided by printing an electrically conductive paste or ink composed of the combination of a resin material and metallic fillers.

In the mounting process, the electronic device is loaded on the electrode pads 3 of the interconnection pattern, provided in the previous step, so that the external electrodes 6 of the device 5 thus loaded are contacted with the electrode pads. The electrically conductive paste or ink, thus applied, are then cured on heating ((E) of FIG. 22).

On the stage 13, provided with a recess (stepped-down portion), interconnections 2 are formed on the surface of the substrate 1 opposite to the substrate surface carrying the device 5, thereby completing the package ((F) of FIG. 22).

As described above, fine metallic particles having a particle size of about 20 nm or less are contained in the electrically conductive members. These fine metallic particles may be sintered at relatively low temperatures (ca. ranging 150 to 250° C.). Thus, with sintering, the electrical conductivity may be improved further. It is the resin contained in the paste or the ink that produces the joining force of the electronic devices 5 loaded. However, the joining may also be by the metal material of the external electrode 6 of the electronic device 5 and the metallic fillers in the paste or ink becoming fused together or otherwise producing an anchoring effect. The joining force may also be developed by both the resin material and the metal material.

There is no limitation to the electrically conductive paste or the electrically conductive ink on the condition that such paste or ink has desired specific electrical conductivity, printability, curing characteristic and reliability. As regards this respect, the present method is similar to the package manufacturing method of the above-described eleventh exemplary embodiment.

The present method is also similar to the package manufacturing method of the above-described eleventh exemplary embodiment in such respect that, for the electrically conductive paste or ink, it is desirable to use a material that may be cured or sintered at a temperature not higher than the melting point of the external electrode 6. Such heating process that is matched to this temperature condition is also preferably used.

There is also no particular limitation to the paste applying method, as with the package manufacturing method of the above-described eleventh exemplary embodiment, provided that the paste applying method used allows the desired pattern of the interconnection to be produced.

The present exemplary embodiment shows a case where the electronic device(s) are mounted only on one substrate side. The electronic devices may be mounted in a similar manner on both sides of the substrate 1 as well.

### (Meritorious Effect of the Sixteenth Exemplary Embodiment)

With the above-described package structure of the present exemplary embodiment, it is possible to change the device loading position, formulation of the devices loaded or the pitch of the external electrodes, as in the eleventh exemplary embodiment described above. It is thus possible to manufacture a package with a high designing degree of freedom. In addition, since the number of the process steps or the volume of the wasted devices may be lesser than with the background technique, it is possible to provide a product lower in cost and which is more benign to environment.

Although the present invention has been described above with reference to certain preferred exemplary embodiments thereof, it is to be noted that the present invention is not limited thereto and may be modified in many ways within the scope of its technical concept.

For example, in the exemplary embodiments connected with the package manufacturing method, it is possible to add a process of coating part or entire of the electronic device with an insulating resin, after package manufacture, as in the case of the package structure shown in FIGS. 8 to 13.

As a matter of course, the various exemplary embodiments may be used in combination.

Although the present invention has so far been described with reference to preferred embodiments, the present invention is not to be restricted to the embodiments. The particular exemplary embodiments or examples may be modified or adjusted within the gamut of the entire disclosure of the present invention, inclusive of claims, based on the fundamental technical concept of the invention. Further, variegated combinations or selection of elements disclosed herein may be made within the framework of the claims. That is, further tasks, objects and developments of the present invention will become apparent also from the total disclosure inclusive of claim of the present invention.

In the present invention, various modes are included, e.g., enumerated with “M” as follows.
M1. A package structure for an electronic device having an electronic device mounted on a substrate; the electronic device including an external electrode; the substrate including an interconnection and an electrode pad for mounting the electronic device thereon; wherein part or entire of the interconnection and part or entire of the electrode pad of the substrate are formed of the same material; and wherein the external electrode of the electronic device is joined to the electrode pad of the substrate with a joining part which is the same material as the interconnection and the electrode pad.
M2. A package structure for an electronic device having an electronic device mounted on a substrate; the electronic device including an external electrode; the substrate including an interconnection and an electrode pad for mounting the electronic device thereon; wherein part or entire of the interconnection and part or entire of the electrode pad of the substrate are formed of the same material as and thus formed integrally with a joining part that joins the electrode pad of the substrate to the external electrode of the electronic device.
M3. A package structure for an electronic device having an electronic device mounted on a substrate; the electronic device including an external electrode; the substrate including an interconnection and an electrode pad for mounting the electronic device thereon; wherein part of the interconnection and part or entire of the electrode pad of the substrate are connected to and extend from an electrically conductive layer provided preliminarily on the substrate; and wherein the external electrode of the electronic device is joined to the electrode pad of the substrate by a joining part of the same material as a material of the interconnection and the electrode pad.
M4. A package structure for an electronic device having an electronic device mounted on a substrate; the electronic device including an external electrode; the substrate including an interconnection and an electrode pad for mounting the electronic device thereon; wherein part of the interconnection and part or entire of the electrode pad of the substrate are connected to and extend from an electrically conductive layer provided preliminarily on the substrate; and wherein the interconnection and the electrode pad are formed of the same material as and are formed integrally with a joining part that joins the electrode pad to the external electrode of the electronic device.
M5. The package structure for an electronic device according to any one of the modes M1 to M4, wherein the interconnection, the electrode pad and the joining part are formed of an electrically conductive paste or an electrically conductive ink.
M6. The package structure for an electronic device according to any one of the modes M1 to M4, wherein the interconnection, the electrode pad and the joining part are formed of an electrically conductive paste or an electrically conductive ink containing metallic particles of a particle size not larger than 5 μm as electrically conductive fillers.
M7. The package structure for an electronic device according to any one of the modes M1 to M4, wherein the interconnection, the electrode pad and the joining part are formed of an electrically conductive paste or an electrically conductive ink containing fine metallic particles of the particle size not larger than 20 nm as at least part of electrically conductive fillers.
M8. The package structure for an electronic device according to any one of the modes M1 to M4, wherein the interconnection, the electrode pad and the joining part are formed of an electrically conductive paste or an electrically conductive ink containing both metallic particles of the particle size not larger than 5 μm and fine metallic particles of the particle size not larger than 20 nm as electrically conductive fillers.
M9. The package structure for an electronic device according to mode M7 or M8, wherein the fine metallic particles of the particle size not larger than 20 nm are contained in an amount of 5 to 30 wt % in the electrically conductive paste or the electrically conductive ink.
M10. The package structure for an electronic device according to any one of the modes M1 to M9, wherein a resin material at an interconnection part of the substrate has a thickness thicker than that of a resin material at an electrode pad part thereof.
M11. A method for manufacturing a package of an electronic device having an electronic device mounted on a substrate; the electronic device including an external electrode; the substrate including an interconnection and an electrode pad for mounting the electronic device thereon; the method comprising: forming part or entire of the interconnection and part or entire of the electrode pad of the substrate of the same material as a joining part that joins the electrode pad of the substrate to the external electrode of the electronic device by a lumped forming operation.
M12. A method for manufacturing a package of an electronic device having an electronic device mounted on a substrate; the electronic device including an external electrode; the substrate including an interconnection and an electrode pad for mounting the electronic device thereon; wherein part or entire of the interconnection and part or entire of the electrode pad of the substrate are connected to and extend from an electrically conductive layer or land provided preliminarily on the substrate; the method comprising: forming the interconnection, the electrode pad and a joining part that joins the electrode pad and the external electrode of the electronic device with the same material by a lumped forming operation.
M13. A method for manufacturing a package of an electronic device having an electronic device mounted on a substrate; the electronic device including an external electrode; the substrate including an interconnection and an electrode pad for mounting the electronic device thereon; the method comprising: forming part or entire of the interconnection and part or entire of the shape of the electrode pad of the substrate by printing an electrically conductive paste or an electrically conductive ink; loading the electronic device while the electrically conductive paste or the electrically conductive ink is as yet in an uncured state; loading the external electrode of the electronic device in an area of the substrate printed to a shape of the electrode part; and curing the electrically conductive paste or the electrically conductive ink to form the interconnection of the substrate, the electrode pad of the substrate and a joining part that joins the electrode pad of the substrate to the external electrode with the same material by a lumped forming operation.
M14. The method for manufacturing a package of an electronic device according to mode M13, wherein the electrically conductive paste or the electrically conductive ink is printed in lump by screen printing.
M15. The method for manufacturing a package of an electronic device according to mode M13, wherein the electrically conductive paste or the electrically conductive ink is applied by a dispenser.
M16. The method for manufacturing a package of an electronic device according to mode M13, wherein the electrically conductive paste or the electrically conductive ink is applied in accordance with an ink jet system.
M17. A method for manufacturing a package of an electronic device having an electronic device mounted on a substrate; the electronic device including an external electrode; the substrate including an interconnection and an electrode pad for mounting the electronic device thereon; the method comprising: forming part of the interconnection and part or entire of the shape of the electrode pad of the substrate by printing an electrically conductive paste or an electrically conductive ink so that the part of the interconnection and the part or entire of the shape of the electrode pad of the substrate connect to and extend from at least one of an electrically conductive layer and a land provided preliminary on the substrate; loading the electronic device while the electrically conductive paste or the electrically conductive ink is as yet in an uncured state; loading the external electrode of the electronic device in an area of the substrate printed to the shape of the electrode part; and curing the electrically conductive paste or the electrically conductive ink to form the interconnection of the substrate, the electrode pad of the substrate and a joining part that joins the electrode pad of the substrate to the external electrode of the electronic device with the same material by a lumped forming operation.
M18. The method for manufacturing a package of an electronic device according to mode M17, wherein the electrically conductive paste or the electrically conductive ink is printed in lump by screen printing.
M19. The method for manufacturing a package of an electronic device according to mode M17, wherein the electrically conductive paste or the electrically conductive ink is applied by a dispenser.
M20. The method for manufacturing a package of an electronic device according to mode M17, wherein the electrically conductive paste or the electrically conductive ink is applied in accordance with an ink jet system.
M21. The method for manufacturing a package of an electronic device according to any one of modes M11 to M20, wherein the substrate is formed so that a resin material at an electrode pad part thereof has a thickness thicker than that of a resin material at an interconnection part thereof.

What is claimed is:

1. A package structure for an electronic device having an electronic device mounted on a substrate; said electronic device including an external electrode; said substrate including an interconnection and an electrode pad for mounting said electronic device thereon; wherein
part or entire of said interconnection and part or entire of said electrode pad of said substrate are formed of the same material; and wherein
said external electrode of said electronic device is joined to said electrode pad of said substrate with a joining part which is the same material as said interconnection and said electrode pad.

2. The package structure for an electronic device according to claim 1, wherein
part or entire of said interconnection and part or entire of said electrode pad of said substrate are formed of the same material as and thus formed integrally with a joining part that joins said electrode pad of said substrate to said external electrode of said electronic device.

3. The package structure for an electronic according to claim 1, wherein
part of said interconnection and part or entire of said electrode pad of said substrate are connected to and extend from an electrically conductive layer provided preliminarily on said substrate; and wherein
said external electrode of said electronic device is joined to said electrode pad of said substrate by a joining part of the same material as a material of said interconnection and said electrode pad.

4. The package structure for an electronic device according to claim 1, wherein
part of said interconnection and part or entire of said electrode pad of said substrate are connected to and extend from an electrically conductive layer provided preliminarily on said substrate; and wherein
said interconnection and said electrode pad are formed of the same material as and are formed integrally with a joining part that joins said electrode pad to said external electrode of said electronic device.

5. The package structure for an electronic device according to claim 1, wherein said interconnection, said electrode pad and the joining part are formed of an electrically conductive paste or an electrically conductive ink.

6. The package structure for an electronic device according to claim 1, wherein said interconnection, said electrode pad and the joining part are formed of an electrically conductive paste or an electrically conductive ink containing metallic particles of a particle size not larger than 5 μm as electrically conductive fillers.

7. The package structure for an electronic device according to claim 1, wherein said interconnection, said electrode pad and the joining part are formed of an electrically conductive paste or an electrically conductive ink containing fine metallic particles of the particle size not larger than 20 nm as at least part of electrically conductive fillers.

8. The package structure for an electronic device according to claim 1, wherein said interconnection, said electrode pad and the joining part are formed of an electrically conductive paste or an electrically conductive ink containing both metallic particles of the particle size not larger than 5 μm and fine metallic particles of the particle size not larger than 20 nm as electrically conductive fillers.

9. The package structure for an electronic device according to claim 7, wherein said fine metallic particles of the particle size not larger than 20 nm are contained in an amount of 5 to 30 wt % in said electrically conductive paste or said electrically conductive ink.

10. The package structure for an electronic device according to claim 1, wherein a resin material at an interconnection part of said substrate has a thickness thicker than that of a resin material at an electrode pad part thereof

11. A method for manufacturing a package of an electronic device having an electronic device mounted on a substrate; said electronic device including an external electrode; said substrate including an interconnection and an electrode pad for mounting said electronic device thereon; said method comprising:
forming part or entire of said interconnection and part or entire of said electrode pad of said substrate of the same material as a joining part that joins said electrode pad of said substrate to said external electrode of said electronic device by a lumped forming operation.

12. The method for manufacturing a package of an electronic device according to claim 11, wherein
part or entire of said interconnection and part or entire of said electrode pad of said substrate are connected to and extend from an electrically conductive layer or land provided preliminarily on said substrate; said method comprising:
forming said interconnection, said electrode pad and a joining part that joins said electrode pad and said external electrode of said electronic device with the same material by a lumped forming operation.

13. The method for manufacturing a package of an electronic device according to claim 11, wherein said method comprises:
forming part or entire of said interconnection and part or entire of the shape of said electrode pad of said substrate by printing an electrically conductive paste or an electrically conductive ink;
loading said electronic device while said electrically conductive paste or the electrically conductive ink is as yet in an uncured state;
loading said external electrode of said electronic device in an area of said substrate printed to a shape of said electrode part; and
curing said electrically conductive paste or said electrically conductive ink to form said interconnection of said substrate, said electrode pad of said substrate and a joining part that joins said electrode pad of said substrate to said external electrode with the same material by a lumped forming operation.

14. The method for manufacturing a package of an electronic device according to claim 13, wherein said electrically conductive paste or said electrically conductive ink is printed in lump by screen printing.

15. The method for manufacturing a package of an electronic device according to claim 13, wherein said electrically conductive paste or said electrically conductive ink is applied by a dispenser.

16. The method for manufacturing a package of an electronic device according to claim 13, wherein said electrically conductive paste or said electrically conductive ink is applied in accordance with an ink jet system.

17. The method for manufacturing a package of an electronic device according to claim 11, wherein said method comprises:
forming part of said interconnection and part or entire of the shape of said electrode pad of said substrate by printing an electrically conductive paste or an electrically conductive ink so that said part of said interconnection and said part or entire of the shape of said electrode pad of said substrate connect to and extend from at least one of an electrically conductive layer and a land provided preliminary on said substrate;
loading said electronic device while said electrically conductive paste or the electrically conductive ink is as yet in an uncured state;
loading said external electrode of said electronic device in an area of said substrate printed to the shape of said electrode part; and
curing said electrically conductive paste or said electrically conductive ink to form said interconnection of said substrate, said electrode pad of said substrate and a joining part that joins said electrode pad of said substrate to said external electrode of said electronic device with the same material by a lumped forming operation.

18. The method for manufacturing a package of an electronic device according to claim 17, wherein said electrically conductive paste or said electrically conductive ink is printed in lump by screen printing.

19. The method for manufacturing a package of an electronic device according to claim 17, wherein said electrically conductive paste or said electrically conductive ink is applied by a dispenser.

20. The method for manufacturing a package of an electronic device according to claim 17, wherein said electrically conductive paste or said electrically conductive ink is applied in accordance with an ink jet system.

21. (canceled)
